(19) United States
(12) Patent Application Publication
(10) Pub. No.: US 2026/0262397 A1
(43) Pub. Date: Sep. 3, 2026

(54) DISPLAY SUBSTRATE AND DISPLAY DEVICE

(71) Applicant: BOE Technology Group Co., Ltd., Beijing (CN)

(72) Inventors: Tian Dong, Beijing (CN); Jiangnan Lu, Beijing (CN)

(73) Assignee: BOE Technology Group Co., Ltd., Beijing (CN)

(21) Appl. No.: 18/730,972

(22) PCT Filed: Mar. 1, 2023
(86) PCT No.: PCT/CN2023/079136

§ 371 Date: Jul. 22, 2024

(51) Int. Cl. H10K 59/126; H10K 59/131

(52) U.S. Cl. CPC H10K 59/126; H10K 59/131

(57) ABSTRACT

A display substrate and a display device are provided. The display substrate includes: a pixel unit, a semiconductor layer, a first metal layer, a second metal layer and a conductive layer, the pixel unit includes a pixel circuit, the pixel circuit includes a first reset transistor and a threshold compensation transistor, and the first metal layer includes a first reset control signal line and a gate signal line; the semiconductor layer includes a first connection part, an orthographic projection of the first connection part on the base substrate is located between an orthographic projection of the first reset control signal line and an orthographic projection of the gate signal line on the base substrate, and one end of the first connection part is electrically connected with the first electrode of the first reset transistor; the conductive layer includes data lines, and each pixel unit is between two adjacent data lines; the second metal layer includes a plurality of shielding blocks which are in one-to-one correspondence with the pixel units, and the orthographic projection of each shielding block at least partially overlaps with the orthographic projection of the corresponding first connection part on the base substrate, and the orthographic projections of the shielding blocks corresponding to two adjacent columns of pixel units on the base substrate are symmetrical with respect to a straight line that is between two shielding blocks adjacent in the first direction and extends in the second direction.

### TECHNICAL FIELD

Embodiments of the present disclosure relate to a display substrate and a display device.

### BACKGROUND

With the development of display technology, active-matrix organic light-emitting diode (AMOLED) has been widely used in mobile phones, tablet computers, digital cameras and other display devices because of its advantages of self-luminescence, wide viewing angle, high contrast, low power consumption, extremely high response speed, thinness, flexibility and low cost, so it has a high development prospect. With the continuous development of display technology, a flexible display device with AMOLED as a light-emitting device and signal controlled by thin film transistors (TFTs) has become the mainstream product in the display field. With the continuous development of display technology, it has become an inevitable trend to optimize the display effect of display devices.

### SUMMARY

Embodiments of the present disclosure relate to a display substrate and a display device, the semiconductor layer included in the display substrate comprises a first connection part extending in the second direction, and an orthographic projection of the first connection part on the base substrate is between an orthographic projection of the first reset control signal line on the base substrate and an orthographic projection of the gate signal line on the base substrate, and one end of the first connection part is electrically connected to a first electrode of the first reset transistor; the conductive layer comprises data lines extending in the second direction, and each of the pixel units is between two of the data lines adjacent to each other; the second metal layer comprises a plurality of shielding blocks, the plurality of shielding blocks are in one-to-one correspondence with the plurality of pixel units, and an orthographic projection of each of the shielding blocks on the base substrate at least partially overlaps with an orthographic projection of a corresponding one of the first connection part on the base substrate, and orthographic projections of the shielding blocks corresponding to two adjacent columns of the pixel units on the base substrate are symmetrical with respect to a straight line that is between two of the shielding blocks adjacent to each other in the first direction and extends in the second direction, the structural design can shield the parasitic capacitance between the data line and the gate electrode of the driving transistor, reduce the longitudinal crosstalk, and reduce the flicker problem.

At least one embodiment of the present disclosure provides a display substrate, and the display substrate comprises: a base substrate; a plurality of pixel units, on the base substrate, each of the pixel units comprises a pixel circuit, the pixel circuit comprises a first reset transistor and a threshold compensation transistor; the display substrate further comprises a semiconductor layer, a first metal layer, a second metal layer and a conductive layer which are stacked on the base substrate, the first metal layer comprises a first reset control signal line and a gate signal line that extend in a first direction and are arranged in a second direction, and the first direction intersects the second direction; the semiconductor layer comprises a first connection part extending in the second direction, and an orthographic projection of the first connection part on the base substrate is between an orthographic projection of the first reset control signal line on the base substrate and an orthographic projection of the gate signal line on the base substrate, and one end of the first connection part is electrically connected to a first electrode of the first reset transistor; the conductive layer comprises data lines extending in the second direction, and each of the pixel units is between two of the data lines adjacent to each other; the second metal layer comprises a plurality of shielding blocks, the plurality of shielding blocks are in one-to-one correspondence with the plurality of pixel units, and an orthographic projection of each of the shielding blocks on the base substrate at least partially overlaps with an orthographic projection of a corresponding one of the first connection part on the base substrate, and orthographic projections of the shielding blocks corresponding to two adjacent columns of the pixel units on the base substrate are symmetrical with respect to a straight line that is between two of the shielding blocks adjacent to each other in the first direction and extends in the second direction.

For example, in the display substrate provided by at least one embodiment of the present disclosure, the threshold compensation transistor is a double-gate type thin film transistor, and the orthographic projection of each of the shielding blocks on the base substrate at least partially overlaps with an orthographic projection of a conductive active layer between two gate electrodes of the threshold compensation transistor comprised in a corresponding one of the pixel circuit on the base substrate.

For example, in the display substrate provided by at least one embodiment of the present disclosure, each of the shielding blocks comprises a first shielding part extending in a straight line along the second direction, and a second shielding part and a third shielding part that extend in a zigzag line, and the second shielding part and the third shielding part are connected at an end position of the first shielding part close to the second shielding part, and the second shielding part and the third shielding part form an accommodation space so that an orthographic projection of a part of the first connection part on the base substrate is in an orthographic projection of the accommodation space on the base substrate, and an orthographic projection of another part of the first connection part on the base substrate overlaps with an orthographic projection of the first shielding part on the base substrate.

For example, in the display substrate provided by at least one embodiment of the present disclosure, a first sub-shielding part of the second shielding part directly connected to the first shielding part extends in a direction opposite to the first direction, and a second sub-shielding part of the third shielding part directly connected to the first shielding part extends in the first direction, and a length of the first sub-shielding part in the first direction is smaller than that of the second sub-shielding part in the first direction.

For example, in the display substrate provided by at least one embodiment of the present disclosure, an overlapping region formed by overlapping the orthographic projection of the first shielding part on the base substrate and the orthographic projection of the first connection part on the base substrate has a first overlapping area, an overlapping region formed by overlapping an orthographic projection of the third shielding part on the base substrate and the orthographic projection of the conductive active layer between the two gate electrodes of the threshold compensation transistor on the base substrate has a second overlapping area, and the first overlapping area is larger than the second overlapping area.

For example, in the display substrate provided by at least one embodiment of the present disclosure, the data lines are configured to provide data signals to the pixel circuits corresponding to the data lines, and the plurality of the pixel units comprise two adjacent pixel units in a same column, and two of the data lines adjacent to each other are respectively connected to the two adjacent pixel units, and orthographic projections of the two of the data lines adjacent to each other on the base substrate overlap with an orthographic projection of each of the two adjacent pixel units in the same column on the base substrate respectively.

For example, in the display substrate provided by at least one embodiment of the present disclosure, two rows of pixel units arranged in sequence in the second direction and two columns of pixel units arranged in sequence in the first direction constitute a repeating unit, and the pixel unit in a first row and a first column and the pixel unit in the first row and a second column are symmetrical with respect to a straight line extending in the second direction; the pixel unit in the first column and a second row and the pixel unit in the second row and the second column of are symmetrical with respect to a straight line extending in the second direction.

For example, the display substrate provided by at least one embodiment of the present disclosure, further comprises a conductive connection layer arranged between the second metal layer and the conductive layer, the conductive connection layer comprises an initialization signal connection line extending in the second direction, a first initialization signal line and a second initialization signal line are arranged in the second metal layer, the first initialization signal line is closer to the first reset control signal line than the second initialization signal line, and one end of the initialization signal connection line is electrically connected to the second initialization signal line.

For example, in the display substrate provided by at least one embodiment of the present disclosure, the first reset transistor comprises a second electrode, and the second electrode of the first reset transistor comprised in the pixel unit in the first row and the first column and the second electrode of the first reset transistor comprised in the pixel unit in the first row and the second column are both connected to other end of the initialization signal connection line between them.

For example, in the display substrate provided by at least one embodiment of the present disclosure, one of the repeating units corresponds to one of the initialization signal connection line.

For example, in the display substrate provided by at least one embodiment of the present disclosure, the conductive layer further comprises a first power line extending in the second direction, the first power line is between the data lines adjacent to each other, and an orthographic projection of the first power line on the base substrate at least partially overlaps with the orthographic projection of each of the shielding blocks on the base substrate.

For example, in the display substrate provided by at least one embodiment of the present disclosure, the first power line is bent and extended in the second direction, and a same one of the first power line corresponds to a plurality of the pixel units in a same column.

For example, in the display substrate provided by at least one embodiment of the present disclosure, a planar shape of the first power line is a stepped shape.

For example, in the display substrate provided by at least one embodiment of the present disclosure, the conductive connection layer further comprises a power connection line extending in the second direction, and the first power line comprises a first part, a second part and a third part that protrude to a side of the data line corresponding to the first power line, the first part, the second part and the third part are sequentially arranged in the second direction, and an orthographic projection of the first part on the base substrate overlaps with an orthographic projection of the power connection line on the base substrate.

For example, in the display substrate provided by at least one embodiment of the present disclosure, the conductive connection layer further comprises a first connection electrode extending in the second direction, and an orthographic projection of the second part comprised in the first power line on the base substrate overlaps with an orthographic projection of the first connection electrode on the base substrate.

For example, in the display substrate provided by at least one embodiment of the present disclosure, the pixel circuit further comprises a driving transistor, a first power terminal and a storage capacitor, a first electrode plate of the storage capacitor is connected to a gate electrode of the driving transistor, and a second electrode plate of the storage capacitor is connected to the first power terminal, and an orthographic projection of the third part comprised in the first power line overlaps with an orthographic projection of the second electrode plate on the base substrate.

For example, in the display substrate provided by at least one embodiment of the present disclosure, the orthographic projection of the power connection line on the base substrate, the orthographic projection of the first shielding part on the base substrate, and an orthographic projection of a channel region of the first reset transistor on the base substrate overlap.

For example, the display substrate provided by at least one embodiment of the present disclosure, further comprises a second reset control signal line and a light-emitting element, the pixel circuit further comprises a second reset transistor, a gate electrode of the second reset transistor is connected to the second reset control signal line, a first electrode of the second reset transistor is connected to the second initialization signal line, and a second electrode of the second reset transistor is connected to a first electrode of the light-emitting element.

For example, in the display substrate provided by at least one embodiment of the present disclosure, the gate signal line is configured to provide a scan signal to the pixel circuit, and the pixel circuit further comprises a data writing transistor, a gate electrode of the data writing transistor is connected to the gate signal line, a first electrode of the data writing transistor is connected to the data line, and a second electrode of the data writing transistor is connected to a first electrode of the driving transistor.

For example, in the display substrate provided by at least one embodiment of the present disclosure, a first electrode of the threshold compensation transistor is connected to a second electrode of the driving transistor, and a second electrode of the threshold compensation transistor is connected to a gate electrode of the driving transistor; the gate electrode of the threshold compensation transistor is connected to the gate signal line; and the gate electrode of the driving transistor is connected to the second electrode of the threshold compensation transistor.

For example, in the display substrate provided by at least one embodiment of the present disclosure, the pixel circuit further comprises a first light-emitting control transistor and a second light-emitting control transistor, a gate electrode of the first light-emitting control transistor is connected to a light-emitting control signal line, a first electrode of the first light-emitting control transistor is connected to the first power terminal, and a second electrode of the first light-emitting control transistor is connected to a first electrode of the driving transistor; a gate electrode of the second light-emitting control transistor is connected to the light-emitting control signal line, a first electrode of the second light-emitting control transistor is connected to a second electrode of the driving transistor, and a second electrode of the second light-emitting control transistor is connected to a first electrode of the light-emitting element.

At least one embodiment of the present disclosure provides a display device, and the display device comprises any one of the display substrates in the above mentioned embodiments.

### BRIEF DESCRIPTION OF DRAWINGS

In order to more clearly explain the technical solution of the embodiments of the present disclosure, the accompanying drawings of the embodiments will be briefly introduced below. Obviously, the accompanying drawings in the following description only relate to some embodiments of the present disclosure, and are not limited to the present disclosure.

FIG. 1 is a schematic diagram of a 7T1C pixel circuit provided by at least one embodiment of the present disclosure;

FIG. 2 is an operation timing chart of the pixel circuit shown in FIG. 1;

FIG. 3A is a pixel circuit diagram of a display substrate provided by at least one embodiment of the present disclosure;

FIG. 3B is a pixel circuit diagram of another display substrate provided by at least one embodiment of the present disclosure;

FIG. 4 is a schematic planar view of a semiconductor pattern in a display substrate provided by at least one embodiment of the present disclosure;

FIG. 5 is a schematic planar view of a first metal layer in a display substrate provided by at least one embodiment of the present disclosure;

FIG. 6 is a schematic planar view of a second metal layer in a display substrate provided by at least one embodiment of the present disclosure;

FIG. 7 is a schematic planar view of an active layer, a source electrode and a drain electrode of a thin film transistor formed in a display substrate provided by at least one embodiment of the present disclosure;

FIG. 8 is a schematic planar view of via holes formed in an insulation layer of a display substrate provided by at least one embodiment of the present disclosure;

FIG. 9 is a schematic planar view of a conductive connection layer in a display substrate provided by at least one embodiment of the present disclosure;

FIG. 10 is a schematic planar view of a display substrate provided by at least one embodiment of the present disclosure after a conductive connection layer is formed;

FIG. 11 is a schematic planar view of via holes formed in a passivation layer and a first planarization layer in a display substrate provided by at least one embodiment of the present disclosure;

FIG. 12 is a schematic planar view of a conductive layer in a display substrate provided by at least one embodiment of the present disclosure;

FIG. 13 is a schematic planar view of a display substrate provided by at least one embodiment of the present disclosure after a conductive layer is formed;

FIG. 14 is a schematic planar view of a first electrode of a light-emitting element provided by at least one embodiment of the present disclosure;

FIG. 15 is a schematic structural diagram of stack layers of a display substrate provided by at least one embodiment of the present disclosure; and

FIG. 16 is a schematic cross-sectional view of a display substrate provided by at least one embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly.

Unless otherwise defined, the features such as “parallel”, “vertical” and “identical” used in the embodiments of the present disclosure all comprise situations such as “parallel”, “vertical” and “identical” in a strict sense, and situations such as “substantially parallel”, “substantially vertical” and “substantially identical” that contain the cases of certain errors. For example, the above-mentioned term “substantially” means that the difference of the compared objects is within 10% or 5% of the average value of the compared objects. When the number of one component or element is not specified in the following of the embodiments of the present disclosure, it means that the component or element may be one or more, or may be understood as at least one. “At least one” means one or more, and “multiple/a plurality of” means at least two. The term “arranged in a same layer” in the embodiments of the present disclosure refers to the relationship between multiple layers formed by the same material after the same step (for example, one-step patterning process). The term “same layer” here does not always mean that multiple layers with the same thickness or multiple layers with the same height in cross-sectional view.

It should be noted that, for the sake of clarity, in the drawings used to describe the embodiments of the present disclosure, the thickness of the layers or regions is exaggerated. It will be understood that in the case where an element, such as a layer, a film, a region or a substrate, and the like, is referred to as being “on” or “under” another element, the element may be “directly” “on” or “under” another element, or intervening element(s) may exist therebetween.

In the technical field of organic light-emitting diode display, the technical scheme of Dual Source can solve the problem of insufficient compensation time in high-frequency display, but the scheme of Dual Source has the problems of limited pixel layout space and parasitic capacitances between various signal lines in the application of high-resolution display device. At present, there is a great demand for active matrix organic light-emitting diode (AMOLED) display substrates with a high frame rate in the market, for example, the Dual Data scheme can increase the driving frequency on the premise of ensuring the display effect, for example, it can achieve the driving of 120 Hz on the premise of ensuring the display effect.

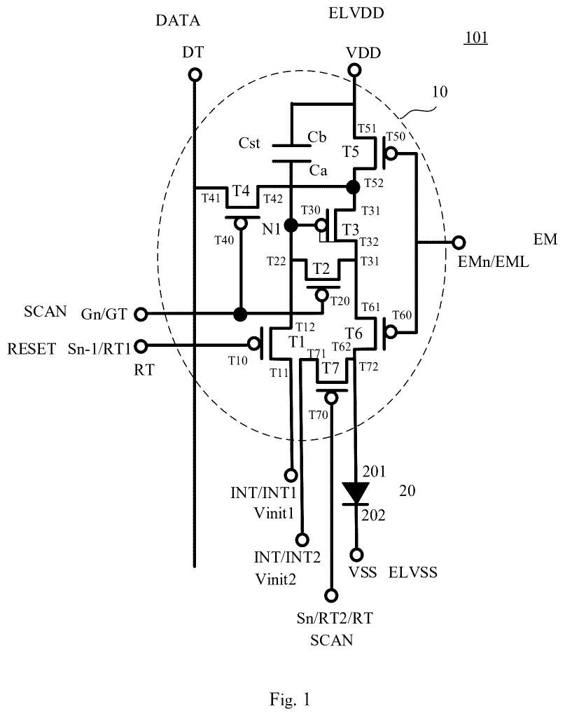

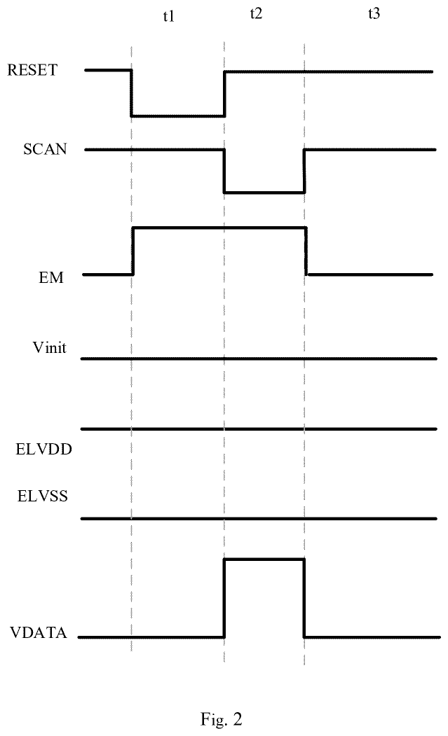

For example, FIG. 1 is a schematic diagram of a 7T1C pixel circuit provided by at least one embodiment of the present disclosure. FIG. 2 is an operation timing chart of the pixel circuit shown in FIG. 1. The pixel circuit shown in FIG. 1 may be a pixel circuit of Low Temperature Poly-Silicon (LTPS) AMOLED which is common in the related art.

For example, FIG. 1 shows a pixel circuit of a pixel unit of a display substrate provided by at least one embodiment of the present disclosure. As shown in FIG. 1, a pixel unit 101 includes a pixel circuit 10 and a light-emitting element 20. The pixel circuit 10 includes six switch transistors (T1-T2 and T4-T7), a driving transistor T3 and a storage capacitor Cst. The six switch transistors are respectively a first reset transistor T1, a threshold compensation transistor T2, a data writing transistor T4, a first light-emitting control transistor T5, a second light-emitting control transistor T6, and a second reset transistor T7. The light-emitting element 20 includes a first electrode 201, a second electrode 202, and a light-emitting function layer located between the first electrode 201 and the second electrode 202. For example, the first electrode 201 is an anode and the second electrode 202 is a cathode. Generally, the threshold compensation transistor T2 and the first reset transistor T1 adopt a double-gate type thin film transistor (TFT) to reduce the leakage current.

For example, as shown in FIG. 1, the display substrate includes a gate signal line GT, a data line DT, a first power terminal VDD, a second power terminal VSS, a light-emitting control signal line EML, an initialization signal line INT, a reset control signal line RT, and the like. For example, the reset control signal line RT includes a first reset control signal line RT1 and a second reset control signal line RT2. The first power terminal VDD is configured to provide a constant first voltage signal ELVDD to the pixel unit 101, and the second power terminal VSS is configured to provide a constant second voltage signal ELVSS to the pixel unit 101, and the first voltage signal ELVDD is greater than the second voltage signal ELVSS. The gate signal line GT is configured to provide a scan signal SCAN to the pixel unit 101, the data line DT is configured to provide a data signal DATA (a data voltage VDATA) to the pixel unit 101, the light-emitting control signal line EML is configured to provide a light-emitting control signal EM to the pixel unit 101, and the first reset control signal line RT1 is configured to provide a reset control signal RESET to the pixel unit 101, the second reset control signal line RT2 is configured to provide a scan signal SCAN to the pixel unit 101, and the initialization signal line INT is configured to provide an initialization signal Vinit to the pixel unit 101. For example, the initialization signal Vinit is a constant voltage signal, and the magnitude of the initialization signal Vinit may be between the first voltage signal ELVDD and the second voltage signal ELVSS, but the embodiments of the present disclosure are not limited to this case, for example, the initialization signal Vinit may be greater than or equal to the second voltage signal ELVSS. For example, the initialization signal line INT includes a first initialization signal line INT1 and a second initialization signal line INT2. For example, the first initialization signal line INT1 is configured to provide an initialization signal Vinit1 to the pixel unit 101, and the second initialization signal line INT1 is configured to provide an initialization signal Vinit2 to the pixel unit 101. For example, in some embodiments, the first initialization signal Vinit1 and the second initialization signal Vinit2 may be equal and both are Vinit.

For example, as shown in FIG. 1, the driving transistor T3 is electrically connected to the light-emitting element 20, and outputs a driving current to drive the light-emitting element 20 to emit light under the control of signals such as the scan signal SCAN, the data signal DATA, the first voltage signal ELVDD, the second voltage signal ELVSS, and the like.

For example, the light-emitting element 20 is an organic light-emitting diode (OLED), and the light-emitting element 20 emits red light, green light, blue light, white light, and the like under the driving of its corresponding pixel circuit 10. For example, one pixel includes a plurality of pixel units. One pixel may include a plurality of pixel units emitting light of different colors. For example, one pixel may include a pixel unit emitting red light, a pixel unit emitting green light and a pixel unit emitting blue light, but embodiments of the present disclosure are not limited thereto. The number of pixel units included in one pixel and the light-emitting situation of each pixel unit may be determined as required, which is not limited by the embodiments of the present disclosure.

For example, as shown in FIG. 1, the gate electrode T40 of the data writing transistor T4 is connected to the gate signal line GT, the first electrode T41 of the data writing transistor T4 is connected to the data line DT, and the second electrode T42 of the data writing transistor T4 is connected to the first electrode T31 of the driving transistor T3.

For example, as shown in FIG. 1, the gate electrode T20 of the threshold compensation transistor T2 is connected to the gate signal line GT, the first electrode T21 of the threshold compensation transistor T2 is connected to the second electrode T32 of the driving transistor T3, and the second electrode T22 of the threshold compensation transistor T2 is connected to the gate electrode T30 of the driving transistor T3.

For example, as shown in FIG. 1, the display substrate further includes a light-emitting control signal line EML, the gate electrode T50 of the first light-emitting control transistor T5 is connected to the light-emitting control signal line EML, the first electrode T51 of the first light-emitting control transistor T5 is connected to the first power terminal VDD, and the second electrode T52 of the first light-emitting control transistor T5 is connected to the first electrode T31 of the driving transistor T3; the gate electrode T60 of the second light-emitting control transistor T6 is connected to the light-emitting control signal line EML, the first electrode T61 of the second light-emitting control transistor T6 is connected to the second electrode T32 of the driving transistor T3, and the second electrode T62 of the second light-emitting control transistor T6 is connected to the first electrode 201 of the light-emitting element 20.

For example, as shown in FIG. 1, the first reset transistor T1 is connected to the gate electrode T30 of the driving transistor T3 and is configured to reset the gate electrode T30 of the driving transistor T3, the second reset transistor T7 is connected to the first electrode 201 of the light-emitting element 20 and is configured to reset the first electrode 201 of the light-emitting element 20. The first initialization signal line INT1 is connected to the gate electrode of the driving transistor T3 through the first reset transistor T1. The second initialization signal line INT2 is connected to the first electrode 201 of the light-emitting element 20 through the second reset transistor T7. For example, the first initialization signal line INT1 and the second initialization signal line INT2 may be connected to be input the same initialization signal, but the embodiments of the present disclosure are not limited to this case, and in some embodiments, the first initialization signal line INT1 and the second initialization signal line INT2 may also be insulated from each other and are configured to input different initialization signals respectively.

For example, as shown in FIG. 1, the first electrode T11 of the first reset transistor T1 is connected to the first initialization signal line INT1, the second electrode T12 of the first reset transistor T1 is connected to the gate electrode T30 of the driving transistor T3, the first electrode T71 of the second reset transistor T7 is connected to the second initialization signal line INT2, and the second electrode T72 of the second reset transistor T7 is connected to the first electrode 201 of the light-emitting element 20. For example, as shown in FIG. 1, the gate electrode T10 of the first reset transistor T1 is connected to the first reset control signal line RT1, and the gate electrode T70 of the second reset transistor T7 is connected to the second reset control signal line RT2.

For example, as shown in FIG. 1, the first power terminal VDD is configured to provide a first voltage signal ELVDD to the pixel circuit 10; the pixel circuit further includes a storage capacitor Cst, the first electrode plate Ca of the storage capacitor Cst is connected to the gate electrode T30 of the driving transistor T3, and the second electrode plate Cb of the storage capacitor Cst is connected to the first power terminal VDD.

For example, as shown in FIG. 1, the display substrate further includes a second power terminal VSS, and the second power terminal VSS is connected to the second electrode 201 of the light-emitting element 20.

For example, as shown in FIG. 2, in a display time period of one frame, the driving method of the pixel unit includes a first reset phase t1, a data writing and threshold compensation phase and a second reset phase t2, and a light-emitting phase t3. When the reset control signal RESET is at a low level, the gate electrode of the driving transistor T3 is reset, and when the scan signal SCAN is at a low level, the first electrode 201 (e.g., the anode) of the light-emitting element 20 is reset. For example, as shown in FIG. 1, when the scan signal SCAN is at a low level, the data voltage VDATA is written, and at the same time, the threshold voltage Vth of the driving transistor T3 is obtained, and the data voltage VDADA containing the data information on the data line is stored in the capacitor Cst; when the light-emitting control signal line EML is at a low level, the light-emitting element 20 emits light, and the voltage of the first node N1 (a gate electrode point) (light-emitting stability of the light-emitting element 20) is held by the storage capacitor Cst. In the driving process of the pixel circuit 10, in the light-emitting phase, the storage capacitor is used to hold the voltage signal, so that the potential at the signal holding end is kept constant, and a voltage difference is formed between the gate electrode and the source electrode of the driving transistor, thereby controlling the driving transistor to form the driving current, and further driving the light-emitting element 20 to emit light.

For example, as shown in FIG. 2, in the reset phase t1, the light-emitting control signal EM is set as a turn-off voltage, the reset control signal RESET is set as a turn-on voltage, and the scan signal SCAN is set as a turn-off voltage.

For example, as shown in FIG. 2, in the data writing and threshold compensation phase and the second reset phase t2, the light-emitting control signal EM is set as a turn-off voltage, the reset control signal Reset is set as a turn-off voltage, and the scan signal SCAN is set as a turn-on voltage.

For example, as shown in FIG. 2, in the light-emitting phase t3, the light-emitting control signal EM is set as a turn-on voltage, the reset control signal RESET is set as a turn-off voltage, and the scan signal SCAN is set as a turn-off voltage.

For example, as shown in FIG. 2, the first voltage signal ELVDD and the second voltage signal ELVSS are both constant voltage signals, for example, the initialization signal Vinit is between the first voltage signal ELVDD and the second voltage signal ELVSS.

For example, the turn-on voltage in the embodiments of the present disclosure refers to the voltage that can enable the first electrode and the second electrode of the corresponding transistor to be conductive, and the turn-off voltage refers to the voltage that can enable the first electrode and the second electrode of the corresponding transistor to be not conductive. In the case where the transistor is a P-type transistor, the turn-on voltage is in low voltage (for example, 0V) and the turn-off voltage is a high voltage (for example, 5V); in the case where the transistor is an N-type transistor, the turn-on voltage is a high voltage (for example, 5V) and the turn-off voltage is a low voltage (for example, 0V). The driving waveforms shown in FIG. 2 are all explained by taking the transistors as P-type transistors. For example, the turn-on voltage is a low voltage (for example, 0V) and the turn-off voltage is a high voltage (for example, 5V), but the embodiments of the present disclosure are not limited to this case.

For example, in combination with FIG. 1 and FIG. 2, in the first reset phase t1, the light-emitting control signal EM is a turn-off voltage, the reset control signal RESET is a turn-on voltage, and the scan signal SCAN is a turn-off voltage. At this time, the first reset transistor T1 is in a conductive state, while the second reset transistor T7, the data writing transistor T4, the threshold compensation transistor T2, the first light-emitting control transistor T5 and the second light-emitting control transistor T6 are in an off state. The first reset transistor T1 transmits the first initialization signal (initialization voltage Vinit) Vinit1 to the gate electrode of the driving transistor T3 and is stored by the storage capacitor Cst, which resets the driving transistor T3 and erases the data stored during the last light-emitting phase (the previous frame).

In the data writing and threshold compensation phase and the second reset phase t2, the light-emitting control signal EM is a turn-off voltage, the reset control signal RESET is a turn-off voltage, and the scan signal SCAN is a turn-on voltage. At this time, the data writing transistor T4 and the threshold compensation transistor T2 are in a conductive state, and the second reset transistor T7 is in a conductive state, and the second reset transistor T7 transmits a second initialization signal (the initialization voltage Vinit) Vinit2 to the first electrode 201 of the light-emitting element 20 to reset the light-emitting element 20, while the first light-emitting control transistor T5, the second light-emitting control transistor T6 and the first reset transistor T1 are in the off state. At this time, the data writing transistor T4 transmits the data voltage VDATA to the first electrode of the driving transistor T3, that is, the data writing transistor T4 receives the scan signal SCAN and the data voltage VDATA and writes the data voltage VDATA to the first electrode of the driving transistor T3 according to the scan signal SCAN. The conduction of that the threshold compensation transistor T2 is turned on to connect the driving transistor T3 into a diode structure, so that the gate electrode of the driving transistor T3 can be charged. After charging the gate electrode of the driving transistor T3, the gate voltage of the driving transistor T3 is VDATA+Vth, VDATA is the data voltage, and Vth is the threshold voltage of the driving transistor T3, that is, the threshold compensation transistor T2 receives the scan signal SCAN and performs threshold voltage compensation on the gate voltage of the driving transistor T3 according to the scan signal SCAN. In this phase, the voltage difference between two terminals of the storage capacitor Cst is ELVDD-VDATA-Vth.

In the light-emitting phase t3, the light-emitting control signal EM is a turn-on voltage, the reset control signal RESET is a turn-off voltage, and the scan signal SCAN is a turn-off voltage. The first light-emitting control transistor T5 and the second light-emitting control transistor T6 are in the conductive state, while the data writing transistor T4, the threshold compensation transistor T2, the first reset transistor T1 and the second reset transistor T7 are in the off state. The first voltage signal ELVDD is transmitted to the first electrode of the driving transistor T3 through the first light-emitting control transistor T5, and the gate voltage of the driving transistor T3 is held at VDATA+Vth, and the light-emitting current I flows into the light-emitting element 20 through the first light-emitting control transistor T5, the driving transistor T3 and the second light-emitting control transistor T6, so that the light-emitting element 20 emits light. That is, the first light-emitting control transistor T5 and the second light-emitting control transistor T6 receive the light-emitting control signal EM, and control the light-emitting element 20 to emit light according to the light-emitting control signal EM. The luminous current I satisfies the following saturation current formula:

$${K ( Vgs - Vth )}^{2} = {K ( V D A T A + V t h - E L V D D - V t h )}^{2} = {K ( V D A TA - ELVDD )}^{2}$$

in which

$$K = 0.5 {μ}_{n} C o x \frac{W}{L} ,$$

μₙ is the channel mobility of the driving transistor, Cox is the channel capacitance per unit area of the driving transistor T3, W and L are respectively the channel width and the channel length of the driving transistor T3, and Vgs is the voltage difference between the gate electrode of the driving transistor T3 and the source electrode (that is, the first electrode of the driving transistor T3 in the present embodiment) of the driving transistor T3.

It can be seen from the above formula that the current flowing through the light-emitting element 20 is independent of the threshold voltage of the driving transistor T3. Therefore, the pixel circuit shown in FIG. 1 compensates the threshold voltage of the driving transistor T3 very well.

For example, the ratio of the duration of the light-emitting phase t3 to the display period of one frame can be adjusted. In this way, the luminous brightness can be controlled by adjusting the ratio of the duration of the light-emitting phase t3 to the display period of one frame. For example, by controlling the scan driver circuit in the display substrate or an additional driver circuit, the ratio of the duration of the light-emitting phase t3 to the display period of one frame can be adjusted.

For example, the embodiments of the present disclosure are not limited to the specific pixel circuit shown in FIG. 1, and other pixel circuits that can compensate the driving transistor can be adopted. Based on the description and teaching of the implementation in the embodiments of the present disclosure, other setting modes that can be easily thought of by ordinary skilled in the field without creative work are all within the protection scope of the embodiments of the present disclosure.

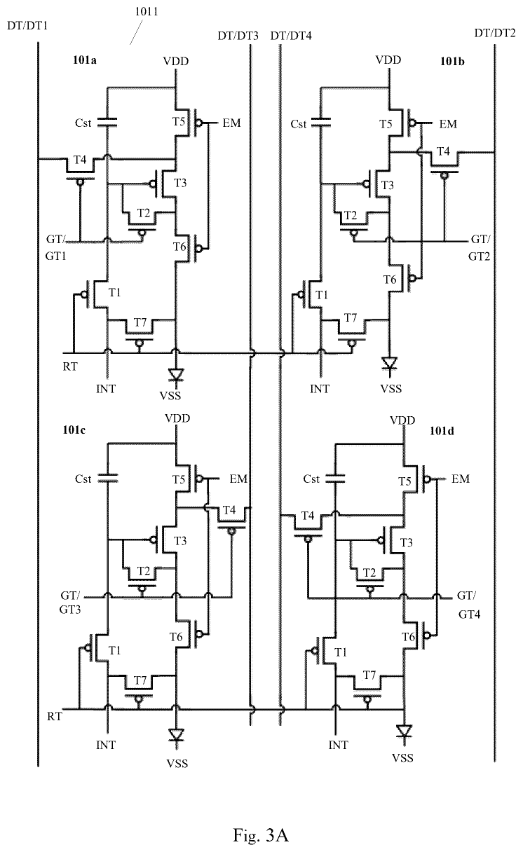

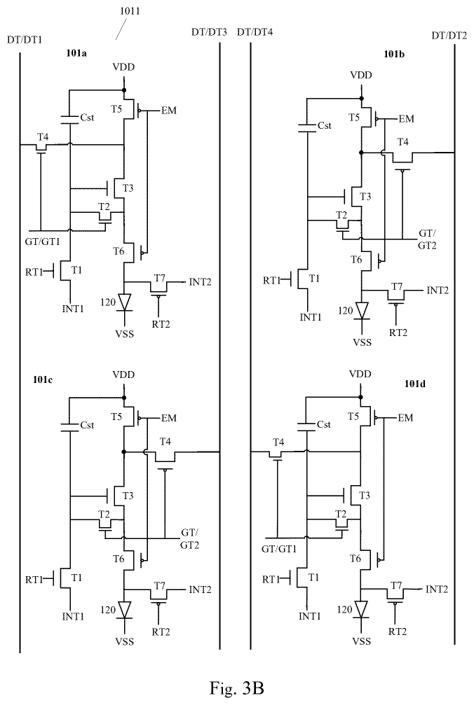

For example, FIG. 3A is a pixel circuit diagram of a display substrate provided by at least one embodiment of the present disclosure. As shown in FIG. 3A, the display substrate includes a base substrate 1011, a first pixel unit 101a, a second pixel unit 101b, a third pixel unit 101c and a fourth pixel unit 101d are arranged on the base substrate 1011, and, the first pixel unit 101a, the second pixel unit 101b, the third pixel unit 101c and the fourth pixel unit 101d, and another four pixel units which are symmetrical with a whole formed by the above four pixels with respect to an axis Y along the second direction, constitute a repeating unit. A plurality of repeating units may form an array.

For example, the display substrate is driven by a mode of dual data lines, so that the first pixel unit 101a, the second pixel unit 101b, the third pixel unit 101c and the fourth pixel unit 101d can be independently controlled by the corresponding data line. In the process of driving the display substrate, the first pixel unit 101a, the second pixel unit 101b, the third pixel unit 101c and the fourth pixel unit 101d are respectively lit in turn, and each pixel unit can have enough compensation time.

For example, as shown in FIG. 3A, the first pixel unit 101a and the second pixel unit 101b are located in the same row and adjacent columns, and the third pixel unit 101c and the fourth pixel unit 101d are located in the same row and adjacent columns. The first pixel unit 101a and the third pixel unit 101c are located in the same column and adjacent rows, and the second pixel unit 101b and the fourth pixel unit 101d are located in the same column and adjacent rows.

For example, FIG. 3B is a pixel circuit diagram of another display substrate provided by at least one embodiment of the present disclosure. One difference between FIG. 3A and FIG. 3B is that in FIG. 3A, in the same pixel unit, the first reset transistor T1 and the second reset transistor T7 are connected to the same initialization signal line INT; in FIG. 3B, in the same pixel unit, the first reset transistor T1 and the second reset transistor T7 are connected to different initialization signal lines, the first reset transistor T1 is connected to the first initialization signal line INT1, and the second reset transistor T7 is connected to the second initialization signal line INT2.

For example, another difference between FIG. 3A and FIG. 3B is that in FIG. 3A, in the same pixel unit, the first reset transistor T1 and the second reset transistor T7 are connected to the same reset control signal line RT to be input with the same reset control signal at the same time; in FIG. 3B, in the same pixel unit, the first reset transistor T1 and the second reset transistor T7 are connected to different reset control signal lines RT, the first reset transistor T1 is connected to the first reset control signal line RT1, and the second reset transistor T7 is connected to the second reset control signal line RT2.

For example, a first data line DT1, a second data line DT2, a third data line DT3 and a fourth data line DT4 are shown in FIG. 3A and FIG. 3B. Referring to FIG. 3A and FIG. 3B, the first data line DT1 is connected to the first pixel unit 101a, the second data line DT2 is connected to the second pixel unit 101b, the third data line DT3 is connected to the third pixel unit 101c, and the fourth data line DT4 is connected to the fourth pixel unit 101d.

For example, in the same pixel unit, in the case where the first reset transistor T1 and the second reset transistor T7 are respectively connected to the first reset control signal line RT1 and the second reset control signal line RT2, the first reset control signal line RT1 and the second reset control signal line RT2 are insulated from each other to be respectively input with corresponding reset control signals. In this case, the reset control signal is input to the first reset transistor T1 and the second reset transistor T7 at different times. As mentioned above, the first reset transistor T1 is input with the reset control signal RESET, and the second reset transistor T7 is input with the scan signal SCAN in the data writing and threshold compensation phase and the second reset phase t2. For example, the gate signal line GT of the present stage is connected to the reset control signal line RT of the next phase. For example, the gate signal line GT and the second reset control signal line RT2 may be electrically connected to input the same signal at the same time.

For example, in the conventional technology, the gate electrode T30 of the driving transistor T3 is in a Floating state at the light-emitting phase, and is held by the storage capacitor Cst. Due to the existence of parasitic capacitance between the gate electrode and the data line, the data signal jump will be coupled to the gate signal part (the first node N1) of the driving transistor and cannot be restored to the initial state, thereby resulting in longitudinal crosstalk. The inventor of the present disclosure noted that it is possible to consider designing a display substrate, the display substrate includes a base substrate on which a plurality of pixel units are arranged, each pixel unit includes a pixel circuit including a first reset transistor and a threshold compensation transistor; the display substrate further comprises a semiconductor layer, a first metal layer, a second metal layer and a conductive layer which are stacked on the base substrate, the first metal layer comprises a first reset control signal line and a gate signal line which extend in a first direction and are arranged in a second direction, and the first direction intersects the second direction; the semiconductor layer comprises a first connection part extending in the second direction, the orthographic projection of the first connection part on the base substrate is between the orthographic projection of the first reset control signal line and the orthographic projection of the gate signal line on the base substrate, and one end of the first connection part is electrically connected to the first electrode of the first reset transistor; the conductive layer includes data lines extending in the second direction, and each pixel unit is arranged between two adjacent data lines; the second metal layer comprises a plurality of shielding blocks, the plurality of shielding blocks are in one-to-one correspondence with the pixel units, the orthographic projection of each of the shielding blocks on the base substrate at least partially overlaps with the orthographic projection of the corresponding first connection part on the base substrate, and the orthographic projections of the shielding blocks corresponding to two adjacent columns of pixel units on the base substrate are symmetrical with respect to a straight line that is between two shielding blocks adjacent in the first direction and extends in the second direction, because the plurality of shielding blocks are in one-to-one correspondence with the plurality of pixel units, the orthographic projection of each of the shielding blocks on the base substrate at least partially overlaps with the orthographic projection of the corresponding first connection part on the base substrate, and the orthographic projections of the shielding blocks corresponding to two adjacent columns of pixel units on the base substrate are symmetrical with respect to a straight line that is between two shielding blocks adjacent in the first direction and extends in the second direction, shielding parasitic capacitance can be realized and longitudinal crosstalk can be reduced, and the problem of flicker can be reduced. The display substrate will be described in detail below in combination with various single-layer structures, partial stacked structures and a structure with all the stacked layers in the display substrate.

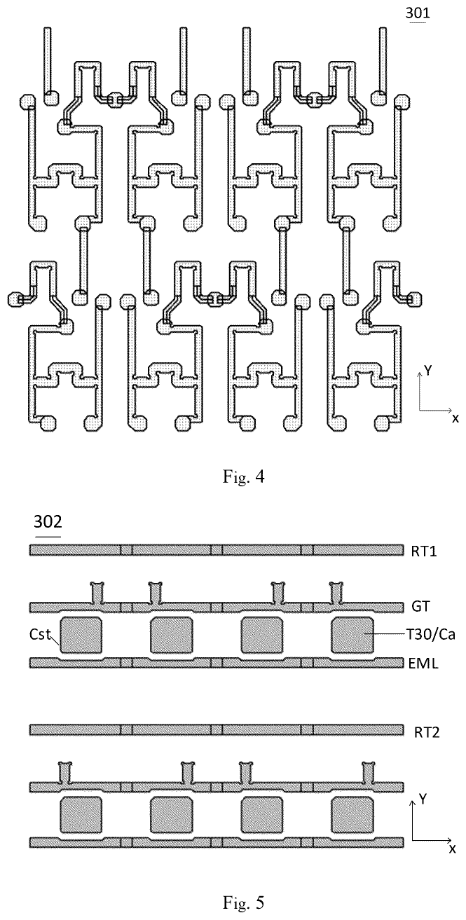

Hereinafter, each layer structure of a display substrate provided by an embodiment of the present disclosure will be described with reference to FIG. 4 to FIG. 16. It should be noted that in the embodiment of the present disclosure, in order to clearly show relevant structures, the insulation layer is shown in the form of via holes in the schematic diagram of the plane structure shown in FIG. 4 to FIG. 16, and the insulation layer itself is illustrated to be transparent, and in each stacked structure, each metal layer and each conductive layer are illustrated to be semi-transparent to reflect the overlapping positional relationship of the various layers.

For example, FIG. 4 is a schematic planar view of a semiconductor pattern in a display substrate provided by at least one embodiment of the present disclosure. FIG. 5 is a schematic planar view of a first metal layer in a display substrate provided by at least one embodiment of the present disclosure. Combined with FIG. 4 and FIG. 5, FIG. 4 shows a semiconductor layer 301, and FIG. 5 shows a first metal layer 302, for example, a first gate insulation layer (a first gate insulation layer GI1, refer to the subsequent schematic cross-sectional structure) is arranged between the first metal layer 302 and the semiconductor layer 301. For example, the semiconductor layer 301 and the subsequent layers in an overall structure in which the layers are sequentially stacked are formed on the base substrate 1011 (shown in FIG. 3A and FIG. 3B).

For example, as shown in FIG. 4, in the first direction X, parts of semiconductor layers of thin film transistors corresponding to any two adjacent pixel units located in the same row are all symmetrical with respect to a straight line extending in the second direction Y.

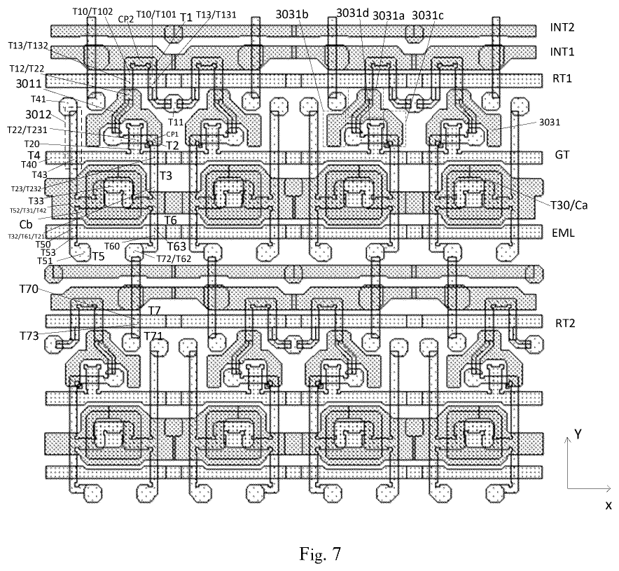

For example, as shown in FIG. 5, the first metal layer 302 includes a first reset control signal line RT1, a gate signal line GT, a light-emitting control signal line EML and a second reset control signal line RT2 that extend in the first direction X and are arranged in the second direction Y, the first metal layer 302 further includes a first electrode plate Ca (i.e., the gate electrode T30 of the driving transistor T3 in combination with FIG. 1) of the storage capacitor Cst, the first electrode plate Ca of the storage capacitor Cst is located between the gate signal line GT and the light-emitting control signal line EML in the second direction Y. The first direction X intersects the second direction Y. The semiconductor layer 301 is doped using the first metal layer 302 as a mask, so that the region of the semiconductor layer 301 covered by the first metal layer 302 retains the semiconductor characteristics and forms an active layer (referring to the following FIG. 7), while the region of the semiconductor layer 301 not covered by the first metal layer 302 is treated to be conductive to form the source electrode and the drain electrode of the thin film transistor. FIG. 7 shows the active layer formed after the semiconductor layer is partially treated to be conductive. For example, in the embodiment of the present disclosure, the gate signal line GT of the present stage is connected to the reset control signal line of the next stage. For example, the gate signal line GT and the second reset control signal line RT2 may be electrically connected to input the same signal at the same time.

For example, the gate signal line is configured to provide a scan signal to the pixel circuit, and the pixel circuit further includes a data writing transistor, the gate electrode of the data writing transistor is connected to the gate signal line, the first electrode of the data writing transistor is connected to the data line, and the second electrode of the data writing transistor is connected to the first electrode of the driving transistor.

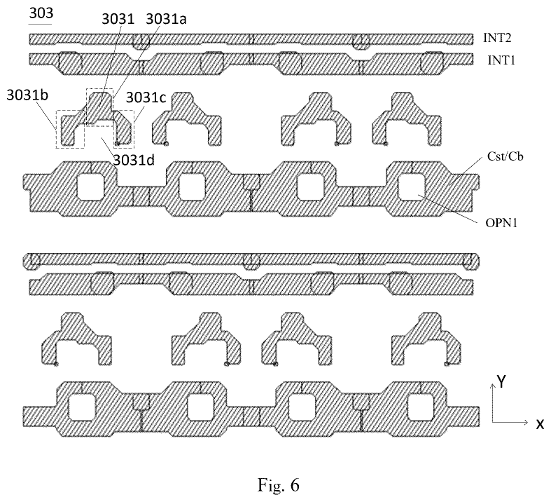

For example, FIG. 6 is a schematic planar view of a second metal layer in a display substrate provided by at least one embodiment of the present disclosure. For example, as shown in FIG. 3B and FIG. 6, a second gate insulation layer is provided between the second metal layer 303 and the first metal layer 302. The second metal layer 303 includes a plurality of shielding blocks 3031, the first initialization signal line INT1, the second initialization signal line INT2, and the second electrode plate Cb of the storage capacitor Cst. The plurality of shielding blocks 3031 are in one-to-one correspondence with a plurality of pixel units, and the orthographic projection of each of the shielding blocks 3031 on the base substrate 1011 at least partially overlaps with the orthographic projection of the corresponding first connection part 3011, and the orthographic projections of the shielding blocks 3031 corresponding to two adjacent columns of pixel units on the base substrate 1011 are symmetrical with respect to a straight line that is between two shielding blocks 3031 adjacent in the first direction X and extends in the second direction Y. For example, referring to FIG. 6, the first initialization signal line INT1 extends along the first direction X, and the second initialization signal line INT2 extends along the first direction X. The first initialization signal line INT1 and the second initialization signal line INT2 are arranged in the second direction Y. As shown in FIG. 6, the first initialization signal line INT1 and the second initialization signal line INT2 are located on the same side of the second electrode plate Cb of the storage capacitor Cst, the first initialization signal line INT1 and the second initialization signal line INT2 are located on the same side of the shielding blocks 3031, and in the second direction Y, the shielding blocks 3031 are located between the first initialization signal line INT1 and the second electrode plate Cb of the storage capacitor Cst. As shown in FIG. 6, the second initialization signal line INT2, the first initialization signal line INT1, the shielding blocks 3031 and the second electrode plate Cb of the storage capacitor Cst are sequentially arranged along the second direction Y. The shielding blocks 3031 are electrically connected to the first power line VDD1 (located in the conductive layer mentioned in the following), so that the first power line VDD1 provides a constant voltage for the shielding blocks 3031.

For example, FIG. 7 is a schematic planar view of an active layer, a source electrode and a drain electrode of a thin film transistor formed in a display substrate provided by at least one embodiment of the present disclosure. As shown in FIG. 5 and FIG. 7, in the manufacturing process of the display substrate, using a self-aligned process, the first metal layer 302 is used as a mask for conducting the semiconductor layer 301, for example, the semiconductor layer 301 is heavily doped by an ion implantation process, so that the part of the semiconductor layer 301 not covered by the first metal layer 302 is conductive to form a source region (the first electrode T31) and a drain region (the second electrode T32) of the driving transistor T3, a source region (the first electrode T41) and a drain region (the second electrode T42) of the data writing transistor T4, a source region (the first electrode T21) and a drain region (the second electrode T22) of the threshold compensation transistor T2, and a source region (the first electrode T51) and a drain region (the second electrode T52) of the first light-emitting control transistor T5, a source region (the first electrode T61) and a drain region (the second electrode T62) of the second light-emitting control transistor T6, a source region (the first electrode T11) and a drain region (the second electrode T12) of the first reset transistor T1, and a source region (the first electrode T71) and a drain region (the second electrode T72) of the second reset transistor T7. The part of the semiconductor layer 301 covered by the first metal layer 302 retains semiconductor characteristics to form a channel region T33 of the driving transistor T3, a channel region T43 of the data writing transistor T4, a channel region T23 of the threshold compensation transistor T2, a channel region T53 of the first light-emitting control transistor T5, a channel region T63 of the second light-emitting control transistor T6, a channel region T13 of the first reset transistor T1, and a channel region T73 of the second reset transistor T7. The channel region of each transistor constitutes the active layer of the respective transistor.

For example, as shown in FIG. 7, the second electrode T72 of the second reset transistor T7 and the second electrode T62 of the second light-emitting control transistor T6 are integrally formed; the first electrode T61 of the second light-emitting control transistor T6, the second electrode T32 of the driving transistor T3 and the first electrode T21 of the threshold compensation transistor T2 are integrally formed; the first electrode T31 of the driving transistor T3, the second electrode T42 of the data writing transistor T4 and the second electrode T52 of the first light-emitting control transistor T5 are integrally formed; the second electrode T22 of the threshold compensation transistor T2 and the second electrode T12 of the first reset transistor T1 are integrally formed.

For example, the display substrate includes a plurality of pixel units arranged on the base substrate, each of the pixel units includes the pixel circuit, and each pixel circuit includes the first reset transistor, the threshold compensation transistor, the second reset transistor, the first light-emitting control transistor, the second light-emitting control transistor, the data writing transistor and the driving transistor mentioned above.

For example, the channel regions (the active layers) of the transistors adopted by the embodiment of the present disclosure may be made of monocrystalline silicon, polycrystalline silicon (e.g., low temperature polycrystalline silicon) or metal oxide semiconductor materials (e.g., IGZO, AZO, etc.). In one embodiment of the present disclosure, the transistors are all P-type low temperature polysilicon (LTPS) thin film transistors. In other embodiments, the threshold compensation transistor T2 and the first reset transistor T1 that are directly connected to the gate electrode of the driving transistor T3 are metal oxide semiconductor thin film transistors, that is, the materials of the channel regions of the transistors are metal oxide semiconductor materials (such as IGZO, AZO, etc.), and the metal oxide semiconductor thin film transistors have lower leakage current, which is helpful to reduce the leakage current of the gate electrode of the driving transistor T3.

For example, the transistors adopted by the embodiments of the present disclosure may include various structures, such as a top-gate type structure, a bottom-gate type structure or a double-gate type structure. In some embodiments of the present disclosure, the threshold compensation transistor T2 and the first reset transistor T1, that are directly connected to the gate electrode of the driving transistor T3, are both double-gate type thin film transistors, and this design helps to reduce the leakage current of the gate electrode of the driving transistor T3.

For example, as shown in FIG. 7, a part of the light-emitting control signal line EML serves as the gate electrode T50 of the first light-emitting control transistor T5, a part of the light-emitting control signal line EML serves as the gate electrode T60 of the second light-emitting control transistor T6, the gate electrode T10 of the first reset transistor T1 is a part of the first reset control signal line RT1, the gate electrode T70 of the second reset transistor T7 is a part of the second reset control signal line RT2, the gate electrode T40 of the data writing transistor T4 is a part of the gate signal line GT, and the gate electrode T20 of the threshold compensation transistor T2 is a part of the gate signal line GT.

For example, as shown in FIG. 7, the threshold compensation transistor T2 is a double-gate type thin film transistor, and the threshold compensation transistor T2 includes a first channel T231 and a second channel T232, the first channel T231 and the second channel T232 are connected by a first conductive connection part CP1. For example, the orthographic projection of the first conductive connection part CP1 on the base substrate 1011 at least partially overlaps with the orthographic projection of the conductive active layer between the two gate electrodes T20 of the threshold compensation transistor T2 on the base substrate 1011. The orthographic projection of the shielding block 3031 on the base substrate 1011 at least partially overlaps with the orthographic projection of the conductive active layer between the two gate electrodes T20 of the threshold compensation transistor T2 included in the corresponding pixel circuit on the base substrate 1011.

For example, as shown in FIG. 7, the first reset transistor T1 is a double-gate type thin film transistor, and includes a first channel T131 and a second channel T132, the first channel T131 and the second channel T132 are connected by a second conductive connection part CP2. For example, the orthographic projection of the second conductive connection part CP2 on the base substrate 1011 at least partially overlaps with the orthographic projection of the conductive active layer between the two gate electrodes T10 of the first reset transistor T1 on the base substrate 1011.

For example, in the conventional technology, in the case where the threshold compensation transistor T2 is a double-gate type thin film transistor, an intermediate node of the threshold compensation transistor T2, that is, the first conductive connection part CP1, will be disturbed by the jump of the scan signal, and the voltage at the intermediate node will increase at the moment when the scan signal is turned off, and the leakage current to the gate electrode of the driving transistor T3 will be aggravated, which will lead to the flicker problem.

For example, in order to reduce the leakage current of the threshold compensation transistor T2, the orthographic projection of the shielding block 3031 on the base substrate 1011 at least partially overlaps with the orthographic projection of the first conductive connection part CP1 on the base substrate 1011, so that a stable capacitance is formed between the shielding block 3031 and the first conductive connection part CP1. Increasing the parasitic capacitance between the intermediate node of the threshold compensation transistor T2 and the first voltage signal ELVDD can reduce the disturbance and reduce the problem of leakage current. For example, as shown in FIG. 7, the orthographic projection of the shielding block 3031 on the base substrate 1011 at least partially overlaps with the orthographic projection of the first conductive connection part CP1 on the base substrate 1011. A capacitance (stable capacitance) is formed between the shielding block 3031 and the first conductive connection part CP1, that is, a stable capacitance is formed to reduce the leakage current, so as to avoid the leakage current generated by the threshold compensation transistor T2 and avoid affecting the display effect of the display substrate.

For example, in the planar view shown in FIG. 7, the shielding block 3031 at least partially overlaps with the first conductive connection part CP1, that is, the shielding block 3031 at least partially overlaps with the conductive active layer between the two gate electrodes T20 of the threshold compensation transistor T2, and the shielding block 3031 is also connected to the data line, and the data line is located on the conductive layer mentioned in the following, so that the parasitic capacitance between the data line and the gate electrode T20 of the threshold compensation transistor T2 can be shielded to reduce the longitudinal crosstalk.

For example, as shown in FIG. 7, the gate signal line GT extends in the first direction X, the first reset control signal line RT1 extends in the first direction X, and the shielding block 3031 is located between the gate signal line GT and the first reset control signal line RT1, so that the position of the shielding block 3031 in the second direction Y is defined.

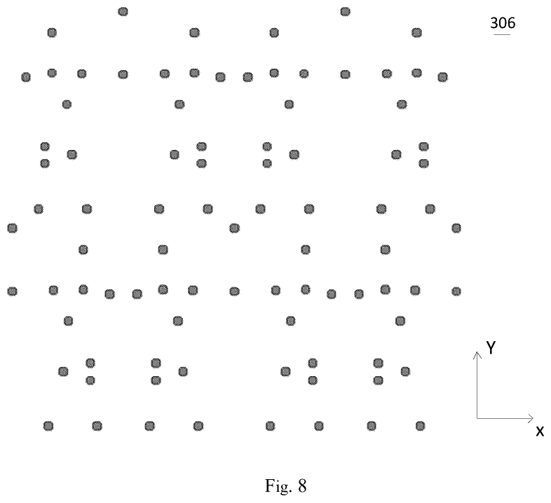

For example, as shown in FIG. 7 and FIG. 8, the orthographic projection of at least a part of the shielding block 3031 on the base substrate 1011 overlaps with the orthographic projection of the first connection part 3011 on the base substrate 1011, and the first connection part 3011 is connected to the gate electrode T30 of the driving transistor T3. The orthographic projection of the first connection part 3011 on the base substrate 1011 at least partially overlaps with the orthographic projection of the shielding block 3031 on the base substrate 1011, so that the shielding block 3031 can shield the parasitic capacitance between the gate electrode of the driving transistor T3 and the data line, so as to reduce the influence of the coupling capacitance and reduce the longitudinal crosstalk.

For example, as shown in FIG. 6 and FIG. 7, each of the shielding blocks 3031 includes a first shielding part 3031a extending along a straight line in the second direction Y, and a second shielding part 3031b and a third shielding part 3031c that extend in a zigzag line, the second shielding part 3031b and the third shielding part 3031c are connected at an end position of the first shielding part 3031a close to the second shielding part 3031b, and the second shielding part 3031b and the third shielding part 3031c form an accommodation space 3031d, so that the orthographic projection of a part of the first connection part 3011 on the base substrate 1011 is located within the orthographic projection of the accommodation space 3031d on the base substrate 1011, and the orthographic projection of another part of the first connection part 3011 overlaps with the orthographic projection of the first shielding part 3031a on the base substrate 1011.

For example, as shown in FIG. 7, in one example, the orthographic projection of the first connection part 3011 on the base substrate 1011 overlaps with the orthographic projection of the first shielding part 3031a on the base substrate 1011.

For example, the first sub-shielding part of the second shielding part 3031b directly connected to the first shielding part 3031a extends along the direction opposite to the first direction X, and the second sub-shielding part of the third shielding part 3031c directly connected to the first shielding part 3031a extends along the first direction X, that is, the first sub-shielding part and the second sub-shielding part extend along the same straight line, and a length of the first sub-shielding part in the first direction X is smaller than that of the second sub-shielding part in the first direction X.

For example, as shown in FIG. 6 and FIG. 7, the overall shape of the shielding block 3031 is in a roof-like shape, and the second shielding part 3031b and the third shielding part 3031c are not completely symmetrical.

For example, as shown in FIG. 7, the overlapping region formed by overlapping the orthographic projection of the first shielding part 3031a and the orthographic projection of the first connection part 3011 on the base substrate 1011 has a first overlapping area, and the overlapping region formed by overlapping the orthographic projection of the third shielding part 3031c on the base substrate 1011 and the orthographic projection of the conductive active layer between the two gate electrodes of the threshold compensation transistor T2 on the base substrate 1011 has a second overlapping area, and the first overlapping area is larger than the second overlapping area.

For example, in one example, the material of the first connection part 3011 is the same as that of the first conductive connection part CP1. For example, the first connection part 3011 and the first conductive connection part CP1 may be made of the same film through the same process. For example, the material of the first connection part 3011 includes a conductive material doped with a semiconductor material. For example, the material of the first connection part 3011 includes a conductive material obtained by doping polysilicon, but the embodiments of the present disclosure are not limited to this.

For example, as shown in FIG. 7, the first connection part 3011 also serves as the second electrode T12 of the first reset transistor T1, the orthographic projection of the second electrode T12 of the first reset transistor T1 on the base substrate 1011 at least partially overlaps with the orthographic projection of the shielding block 3031 on the base substrate 1011. In the embodiment of the present disclosure, the case where the first connection part 3011 serves as the second electrode T12 of the first reset transistor T1 is taken as an example.

For example, FIG. 8 is a schematic planar view of via holes formed in an insulation layer of a display substrate, the insulation layer includes at least one selected from a group consisting of the first gate insulation layer, a second gate insulation layer and an interlayer insulation layer, that is, the via holes penetrate through all the first gate insulation layer, the second gate insulation layer and the interlayer insulation layer, and for example, in FIG. 8, the insulation layer 306 is taken as the first gate insulation layer, and a plurality of via holes are arranged in the gate insulation layer.

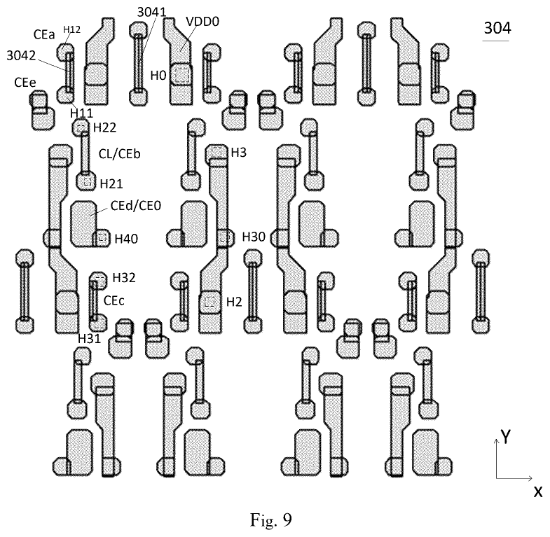

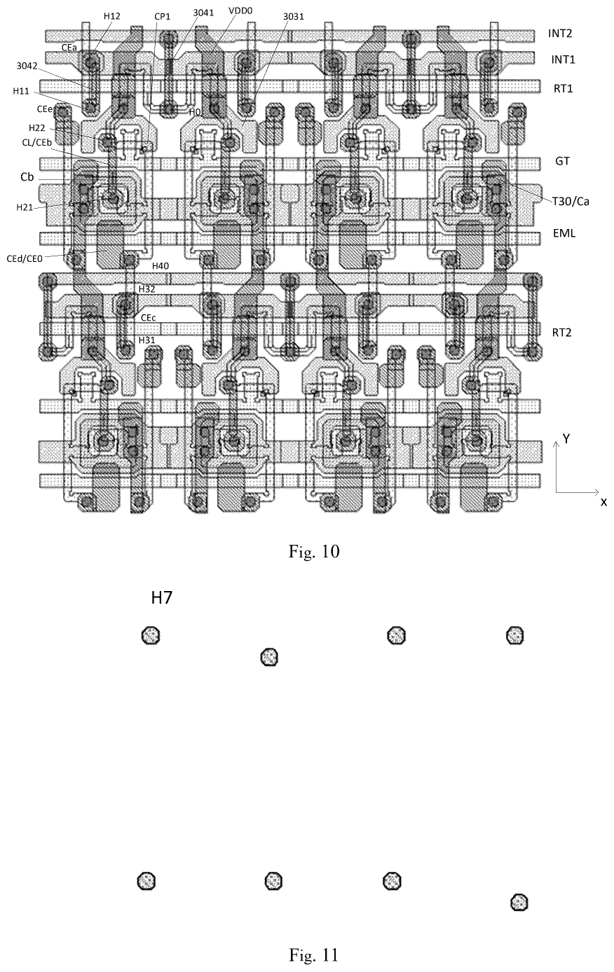

For example, FIG. 9 is a schematic planar view of a conductive connection layer in a display substrate provided by at least one embodiment of the present disclosure. FIG. 10 is a schematic planar view of a display substrate provided by at least one embodiment of the present disclosure after the conductive connection layer is formed.

For example, in combination with FIG. 9 and FIG. 10, the conductive connection layer 304 is disposed between the second metal layer 303 and the conductive layer 305. The conductive connection layer 304 includes an initialization signal connection line 3041 extending in the second direction Y, the second metal layer 303 is provided with a first initialization signal line INT1 and a second initialization signal line INT2, the first initialization signal line INT1 is closer to the first reset control signal line RT1 than the second initialization signal line INT2, and one end of the initialization signal connection line is electrically connected to the second initialization signal line INT2. The conductive connection layer 304 includes a power connection line VDD0, a connection electrode CEa, a connection electrode CEb, a connection electrode CEc, a connection electrode CEd and a connection electrode CEe. An interlayer insulation layer is arranged between the conductive connection layer 304 and the second metal layer 303, that is, the interlayer insulation layer ILD mentioned in the following.

For example, one repeating unit corresponds to one initialization signal connection line 3041, that is, two adjacent pixel units in the first direction X share one initialization signal connection line 3041.

For example, as shown in FIG. 9 and FIG. 10, the second end of the initialization signal connection line 3041 in the second direction Y is electrically connected to the first electrodes T11 of the two first reset transistors T1 respectively included in two pixel units adjacent in the first direction X. This design can reduce the number of the initialization signal connection lines 3041, thus simplifying the structure of the conductive connection layer 304.

For example, as shown in FIG. 9 and FIG. 10, at least a part of the first shielding part 3031a is between the initialization signal connection line 3041 and the connection structure 3042. The second end of the connection structure 3042 extends in the second direction Y to the position of the second shielding part 3031b or the third shielding part 3031c close to the first shielding part 3031a, the connection structure 3042 is also the connection electrode CEa, that is, one end of the connection electrode CEa is electrically connected to the first initialization signal line INT1 through the via hole H12, and the other end of the connection electrode CEa extends in the second direction Y, and the other end of the connection electrode CEa is connected to structures of other layers through the via hole H11.

For example, as shown in FIG. 9 and FIG. 10, the power connection line VDD0 is electrically connected to the first electrode T51 of the first light-emitting control transistor T5 through the via hole H2, the power connection line VDD0 is electrically connected to the second electrode plate Cb of the storage capacitor Cst through the via hole H3 and the via hole H30, and the power connection line VDD0 is electrically connected to the shielding block 3031 through the via hole HO. The connection electrode CEb is also the first connection electrode, one end of the first connection electrode CEb is electrically connected to the second electrode T12 of the first reset transistor T1 through the via hole H22, and the other end of the first connection electrode CEb is electrically connected to the gate electrode T30 of the driving transistor T3 (that is, the first electrode plate Ca of the storage capacitor Cst) through the via hole H21, so that the second electrode T12 of the first reset transistor T1 is electrically connected to the gate electrode T30 of the driving transistor T3 (that is, the first electrode plate Ca of the storage capacitor Cst). One end of the connection electrode CEc is electrically connected to the first initialization signal line INT1 through the via hole H32, and the other end of the connection electrode CEc is electrically connected to the first electrode T71 of the second reset transistor T7 through the via hole H31, so that the first electrode T71 of the second reset transistor T7 is electrically connected to the first initialization signal line INT1. The connection electrode CEd is electrically connected to the second electrode T62 of the second light-emitting control transistor T6 through the via hole H40. The connection electrode CEd can be used to connect with the subsequently formed connection electrode CEf, so that the connection electrode CEd is electrically connected to the first electrode 201 of the light-emitting element 20. The connection electrode CEe is electrically connected to the first electrode T41 of the data writing transistor T4 through the via hole H5, and is configured to be connected to the data line mentioned in the following.

For example, in combination with FIG. 7 and FIG. 10, the semiconductor layer 301 includes a first connection part 3011, in the second direction Y, the first connection part 3011 is between the first reset control signal line RT1 and the gate signal line GT, and one end of the first connection part 3011 is electrically connected to the first electrode T11 of the first reset transistor T1, and extends in the second direction Y; in the first direction X, the first connection part 3011 is between the initialization signal connection line 3041 and the connection structure 3042. This design can reduce the longitudinal crosstalk. For example, the first connection part 3011 is an equipotential structure of the gate electrode of the driving transistor T3.

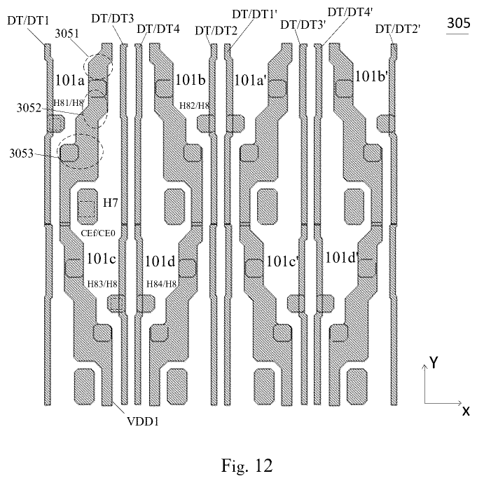

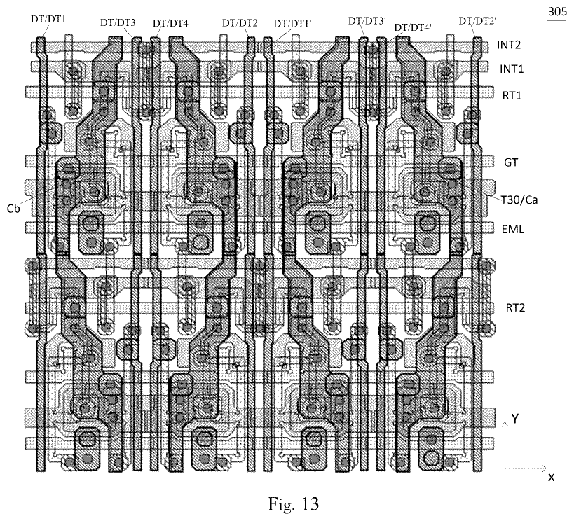

FIG. 11 is a schematic planar view of via holes formed in the passivation layer and the first planarization layer in a display substrate provided by at least one embodiment of the present disclosure, FIG. 12 is a schematic planar view of the conductive layer in a display substrate provided by at least one embodiment of the present disclosure, and FIG. 13 is a schematic planar view of a display substrate after the conductive layer is formed.

For example, in combination with FIG. 12 and FIG. 13, the conductive layer 305 includes a data line DT, a connection electrode CEf, and a first power line VDD1. The data line DT extends in the second direction Y, and the data line DT is configured to provide a data signal to the corresponding pixel circuit. The pixel units include two adjacent pixel units located in the same column, and two adjacent data lines DT are respectively connected to two pixel units, and each of the pixel units is arranged between two adjacent data lines DT. The orthographic projections of two adjacent data lines DT on the base substrate 1011 overlap with the orthographic projection of each of two adjacent pixel units located in the same column on the base substrate 1011.

For example, in combination with FIG. 12 and FIG. 13, a passivation layer (see the passivation layer PVX in the subsequent schematic cross-sectional structure) and a first planarization layer (see the first planarization layer PLN1 in the subsequent schematic cross-sectional structure) are provided between the conductive connection layer 304 and the conductive layer 305. The first power line VDD1 is connected to the power connection line VDD0 through the via hole H6 penetrating the passivation layer and the first planarization layer, and the connection electrode CEf is connected to the connection electrode CEd through the via hole H7 penetrating the passivation layer and the first planarization layer. The data line DT is connected to the connection electrode CEe (not shown in FIG. 16) through the via hole H8 penetrating through the passivation layer and the first planarization layer, and further the data line DT is electrically connected to the first electrode T41 of the data writing transistor T4. For example, the connection electrode CEf and the connection electrode CEd constitute a connection element CEO. For example, the light-emitting element 20 is electrically connected to the pixel circuit 10 through the connection element CEO. For example, the pixel circuit 10 is electrically connected to the connection electrode CEd, the connection electrode CEd is electrically connected to the connection electrode CEf, and the connection electrode CEf is electrically connected to the light-emitting element 20.

For example, as shown in FIG. 12, corresponding to the pixel unit 101a, the pixel unit 101b, the pixel unit 101c and the pixel unit 101d, the via hole H8 penetrating the passivation layer and the first planarization layer includes a via hole H81, a via hole H82, a via hole H83 and a via hole H84.

For example, the first power line VDD1 extends in the second direction Y, the first power line VDD1 is between adjacent data lines DT, and the orthographic projection of the first power line VDD1 on the base substrate 1011 at least partially overlaps with the orthographic projection of the shielding block 3031 on the base substrate 1011.

For example, the first power line VDD1 bends in the second direction Y and extends in the second direction Y, and the same first power line VDD1 corresponds to a plurality of pixel units located in the same column, that is, the same first power line VDD1 is connected to all the pixel units located in the same column, which can reduce the difficulty of manufacturing the first power line VDD1.

For example, the orthographic projection of the first power line VDD1 on the base substrate 1011 overlaps with the orthographic projection of the first initialization signal line, the orthographic projection of the second initialization signal line, the orthographic projection of the first reset control signal line, the orthographic projection of the gate signal line and the orthographic projection of the light-emitting control signal line on the base substrate 1011.

For example, in one example, the planar shape of the first power line VDD1 is in a stepped shape, which can realize that one first power line VDD1 overlaps with the orthographic projections of a plurality of the above structures on the base substrate.

For example, in one example, the orthographic projection of the shielding block 3031 on the base substrate 1011 overlaps with at least a part of the orthographic projection of the data line DT adjacent to the shielding block 3031 on the base substrate 1011, that is, the shielding block 3031, the first connection part 3011 and the data line DT all overlap with each other.

For example, eight via holes H7 are shown in FIG. 11, so that the connection electrode CEf in each of the pixel units can be electrically connected to the connection electrode CEd through the via hole H7 penetrating the passivation layer and the first planarization layer.

For example, as shown in FIG. 12 and FIG. 13, the first power line VDD1 is electrically connected to the second electrode plate Cb of the storage capacitor Cst through the power connection line VDD0.

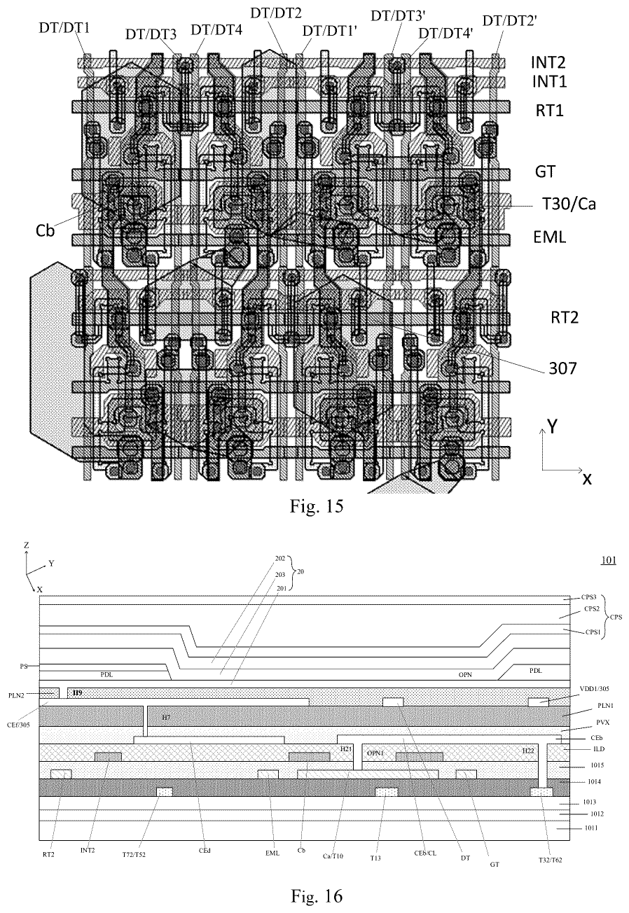

For example, the data lines DT and the connection electrodes CEf are located in the same layer, and both the data lines DT and the connection electrodes CEf are located in the conductive layer 305. The data lines DT include two adjacent data lines DT, and the connection electrode CEf is located between the two adjacent data lines DT. For example, two adjacent data lines DT are arranged in the first direction X, and the data lines DT extend in the second direction. Referring to FIG. 12, FIG. 13 and FIG. 15, the data lines DT include a first data line DT1 and a third data line DT3, the first data line DT1 and the third data line DT3 are adjacent to each other, in the first direction X, the connection electrode CEf is located between the first data line DT1 and the third data line DT3. In the embodiment of the present disclosure, the description like “component A and component B are adjacent” means that there is neither component A nor component B between the component A and the component B. The connection electrode CEf extends along the second direction and is inserted between two adjacent data lines DT, so that the connection electrode CEf not only has the function of connection, but also can shield the parasitic capacitance between the gate signal part of the driving transistor and the data lines, thereby reducing the problem of longitudinal crosstalk. The embodiment of the present disclosure is explained by taking the case where the data lines DT and the connection electrode CEf are located in the same layer as an example. In other embodiments, the data lines DT and the connection electrode CEf may also be located in different layers.

For example, in combination with FIG. 12 and FIG. 13, in one shielding block 3031, the orthographic projection of one of the second shielding part 3031b and the third shielding part 3031c on the base substrate 1011 overlaps with the orthographic projection of the data line DT on the base substrate 1011.

For example, as shown in FIG. 12 and FIG. 13, two columns of pixel units 101 along the first direction X and two rows of pixel units 101 along the second direction Y form one repeating unit, that is, the pixel unit 101a, the pixel unit 101b, the pixel unit 101c and the pixel unit 101d form one repeating unit, and the pixel unit 101a′, the pixel unit 101b′, the pixel unit 101c′ and the pixel unit 101d′ form another repeating unit. For example, in one repeating unit, the pixel unit 101a in the first row and the first column and the pixel unit 101b in the first row and the second column are symmetrical with respect to a straight line extending in the second direction Y; the pixel unit 101c in the first column and the second row and the pixel unit 101d in the second column and the second row are symmetrical with respect to a straight line extending in the second direction Y; the pixel unit 101a in the first row and the first column and the pixel unit 101c in the second row and the first column are symmetrical with respect to a straight line extending in the first direction X; the pixel unit 101b in the first row and the second column and the pixel unit 101d in the second row and the second column are symmetrical with respect to a straight line extending in the first direction X. With reference to FIG. 12, the whole formed by the first power line VDD1 corresponding to the pixel unit 101a which is in the first row and the first column, the first power line VDD1 corresponding to the pixel unit 101b which is in the first row and the second column, the first power line VDD1 corresponding to the pixel unit 101c which is in the second row and the first column, and the first power line VDD1 corresponding to the pixel unit 101d which is in the second row and the second column includes a middle accommodation region, and two adjacent data lines DT are in the middle accommodation region.

For example, the pixel unit 101a in the first row and the first column and the pixel unit 101c in the second row and the first column are not symmetrical with respect to the first direction X, and the pixel unit 101b in the first row and the second column and the pixel unit 101d in the second row and the second column are not symmetrical with respect to the first direction X.

For example, in one example, the second electrode T12 of the first reset transistor T1 included in the pixel unit which is in the first row and the first column and the second electrode T12 of the first reset transistor T1 included in the pixel unit which in the first row and the second column are both connected to the other end of the initialization signal connection line 3041 located therebetween.

For example, FIG. 12 shows a first data line DT1, a second data line DT2, a third data line DT3 and a fourth data line DT4. FIG. 12 also shows the positions of the first pixel unit 101a, the second pixel unit 101b, the third pixel unit 101c and the fourth pixel unit 101d. Actually, eight pixel units are shown in FIG. 12, and the whole constituted by the pixel unit 101a′, the pixel unit 101b′, the pixel unit 101c′ and the pixel unit 101d′ are symmetrical with the whole constituted by the first pixel unit 101a, the second pixel unit 101b, the third pixel unit 101c and the fourth pixel unit 101d with respect to the Y axis (i.e. the second direction).

For example, in one example, as shown in FIG. 9 and FIG. 10, the conductive connection layer 304 further includes a power connection line VDD0 extending in the second direction Y. With reference to FIG. 12 and FIG. 13, the first power line VDD1 includes a first part 3051, a second part 3052 and a third part 3053 that protrude to one side of the corresponding data line DT, and the first part 3051, the second part 3052 and the third part 3053 are sequentially arranged in the second direction Y.

For example, as shown in FIG. 12 and FIG. 13, for the pixel unit 101a, in the stepped shaped first power line VDD1 between the first data line DT1 and the third data line DT3, the first part 3051, the second part 3052 and the third part 3053 sequentially protrude to the side close to the first data line DT1, that is, a distance between the first part 3051 and the corresponding first data line DT1 is larger than that between the second part 3052 and the corresponding first data line DT1, and a distance between the second part 3052 and the corresponding first data line DT1 is larger than that between the third part 3053 and the corresponding first data line DT1. For the pixel unit 101b, in the stepped shaped first power line VDD1 between the fourth data line DT4 and the second data line DT2, the first part 3051, the second part 3052 and the third part 3053 sequentially protrude to the side close to the second data line DT2, that is, the distance between the first part 3051 and its corresponding second data line DT2 is larger than that between the second part 3052 and its corresponding second data line DT2, and the distance between the second part 3052 and its corresponding second data line DT2 is larger than that between the third part 3053 and its corresponding second data line DT2. For the pixel unit 101c, in the stepped shaped first power line VDD1 between the first data line DT1 and the third data line DT3, the first part 3051, the second part 3052 and the third part 3053 sequentially protrude to the side close to the third data line DT3, that is, the distance between the first part 3051 and the corresponding third data line DT3 is larger than that between the second part 3052 and the corresponding third data line DT3, and the distance between the second part 3052 and the corresponding third data line DT3 is larger than that between the third part 3053 and the corresponding third data line DT3. For the pixel unit 101d, in the stepped shaped first power line VDD1 between the fourth data line DT4 and the second data line DT2, the first part 3051, the second part 3052 and the third part 3053 sequentially protrude to the side close to the fourth data line DT4, that is, the distance between the first part 3051 and the corresponding fourth data line DT4 is larger than that between the second part 3052 and the corresponding fourth data line DT4, and the distance between the second part 3052 and the corresponding fourth data line DT4 is larger than that between the third part 3053 and the corresponding fourth data line DT4.

For example, as shown in FIG. 12 and FIG. 13, the orthographic projection of the first part 3051 on the base substrate 1011 overlaps with the orthographic projection of the power connection line VDDD0 on the base substrate 1011, so as to realize the electrical connection between the first power line VDD1 and the power connection line VDDD0.

For example, as shown in FIG. 9, FIG. 10, FIG. 12 and FIG. 13, the conductive connection layer 304 further includes a first connection electrode CEb extending in the second direction Y, the orthographic projection of the second part 3052 included in the first power line VDD1 overlaps with the orthographic projection of the first connection electrode CEb on the base substrate 1011. This design is convenient for realizing the electrical connection between the first power line VDD1 and the first connection electrode CEb.

For example, as shown in FIG. 10, the planar shapes of the second shielding part 3031b and the third shielding part 3031c in each pixel unit 101 both include a shape of an inverted L, and the second shielding part 3031b and the third shielding part 3031c both include a part extending in the lateral direction (that is, the direction parallel to the X axis) and a part extending in the second direction Y.

For example, as shown in FIG. 10, any two adjacent shielding blocks 3031 are spaced apart from each other, but in other embodiments, at least two shielding blocks 3031 arranged in the first direction X may be connected into an integral structure in a plurality of repeating units, or any two adjacent shielding blocks 3031 arranged in the first direction X may be connected into an integral structure in a plurality of repeating units, so that the overall shape of the plurality of shielding blocks 3031 is in a shape of a long stripe, or, in each of the repeating units, two adjacent shielding blocks 3031 may be connected into an integral structure, which is not limited by the embodiments of the present disclosure.

For example, in conjunction with FIG. 1, FIG. 3B and FIG. 10, the first power line VDD1 is configured to provide a first voltage signal ELVDD to the pixel circuit. The first power line VDD1 is electrically connected to the shielding block 3031 to provide a constant voltage for the shielding block 3031. The first power line VDD1 is connected to the first power terminal VDD, and the second electrode plate Cb of the storage capacitor Cst is connected to the first power line VDD1. For example, the second electrode plate Cb of the storage capacitor Cst is connected to the first power terminal VDD through the power connection line VDD0 and the first power line VDD1.

For example, as shown in FIG. 12 and FIG. 13, the first electrode plate Ca of the storage capacitor Cst is connected to the gate electrode of the driving transistor T3, the second electrode plate Cb of the storage capacitor Cst is connected to the first power terminal VDD1, and the orthographic projection of the first power line VDD1 on the base substrate 1011 overlaps with the orthographic projection of the second electrode plate Cb on the base substrate 1011. Specifically, the orthographic projection of the third part 3053 included in the first power line VDD1 on the base substrate 1011 overlaps with the orthographic projection of the second electrode plate Cb on the base substrate 1011.

For example, in one example, the orthographic projection of the power connection line VDD0, the orthographic projection of the first shielding part 3031a and the orthographic projection of the channel region of the first reset transistor T1 on the base substrate 1011 overlap with each other.

For example, the first electrode T51 of the first light-emitting control transistor T5 is connected to the first power terminal VDD through the power connection line VDD0 and the first power line VDD1.

For example, as shown in FIG. 6, FIG. 7, FIG. 10 and FIG. 13, the area of the orthographic projection of the part of the shielding block 3031 overlapping with the first connection part 3011 on the base substrate 1011 is larger than the area of the orthographic projection of the part of the shielding block 3031 overlapping with the first conductive connection part CP1 on the base substrate 1011, but the embodiments of the present disclosure are not limited to this.

For example, as shown in FIG. 13, the orthographic projection of the shielding block 3031 on the base substrate 1011 partially overlaps with the orthographic projection of the third data line DT3 on the base substrate 1011, so that the shielding block 3031 shields the interference between the first data signal on the first data line DT1 and the third data signal on the third data line DT3, and avoids display abnormality caused by coupling.

For example, in the plane structure diagram shown in FIG. 13, one shielding block 3031 corresponds to two pixel units in the same row. As shown in FIG. 13, the shielding block 3031 is located between the first data line DT1 and the second data line DT3.

For example, in the embodiment of the present disclosure, two adjacent elements mean that the two elements are adjacent to each other, and there is no element between them, but it is not excluded that other elements other than such kind of element are arranged between the two adjacent elements.

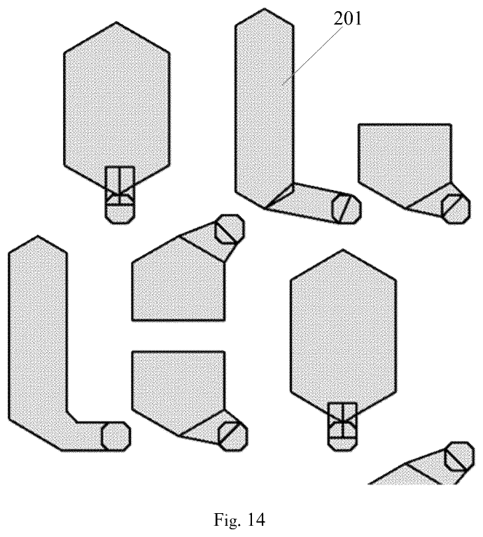

For example, FIG. 14 is a schematic planar view of the first electrode of a light-emitting element provided by at least one embodiment of the present disclosure, FIG. 15 is a schematic structure view of stack layers of a display substrate provided by at least one embodiment of the present disclosure, and FIG. 16 is a schematic cross-sectional structure view of a display substrate provided by at least one embodiment of the present disclosure. It should be noted that the layers on the side of the first electrode of the light-emitting element away from the base substrate is omitted in FIG. 15, and the structure of each layer above the first electrode of the light-emitting element can be referred to the cross-section shown in FIG. 16. Of course, the arrangement position of the first electrode of the light-emitting element and the shape of the first electrode 201 of the light-emitting element are not limited to the structures shown in FIG. 14 and FIG. 15, and those skilled in the art can adjust the arrangement position of the first electrode of the light-emitting element and the planar shape of the first electrode of the light-emitting element as required, which is not limited by the embodiment of the present disclosure.

For example, as shown in FIG. 14, the first electrodes 201 of the light-emitting elements have different planar shapes at positions corresponding to various pixel units. For example, in combination with FIG. 14 and FIG. 15, the planar shape of the first electrode corresponding to the pixel unit 101a is hexagonal, and the planar shape of the first electrode corresponding to the pixel unit 101c includes three parts, which include a part in a shape like an “L” and two pentagonal planar structures corresponding to the part in a shape like an “L”. The planar shape of the first electrode corresponding to the pixel unit 101b includes two parts, which include a part in a shape like an “L” and a part in a regular pentagonal shape corresponding to the part in the shape like an “L”. The planar shape of the first electrode 201 corresponding to the pixel unit 101d is hexagonal.

For example, as shown in FIG. 15, the first electrode 201 of each of the light-emitting elements is electrically connected to the conductive layer 305 through the corresponding via hole. For example, the light-emitting element can be referred to a conventional structure, the light-emitting element may include an organic light-emitting diode, and the light-emitting element includes a first electrode and a second electrode. The light-emitting function layer is located between the second electrode and the first electrode. The second electrode is located on a side of the first electrode away from the base substrate, and the light-emitting function layer at least includes a light-emitting layer, and may also include at least one selected from a group consisting of a hole transport layer, a hole injection layer, an electron transport layer and an electron injection layer. In the structure shown in FIG. 15, the corresponding features of other layers can be referred to the above-mentioned related descriptions, which are not limited by the embodiments of the present disclosure.

For example, the gate electrode of the second reset transistor T7 is connected to the second reset control signal line RT2, the first electrode of the second reset transistor T7 is connected to the second initialization signal line, and the second electrode of the second reset transistor T7 is connected to the first electrode 201 of the light-emitting element 20.

For example, as shown in FIG. 16, both the first direction X and the second direction Y are parallel to the base substrate 1011. For example, the first direction X is perpendicular to the second direction Y. FIG. 16 shows a third direction Z, the third direction Z is perpendicular to the main surface of the base substrate 1011, that is, the third direction Z is perpendicular to the first direction X and perpendicular to the second direction Y. A buffer layer 1012 is disposed on the base substrate 1011, and an isolation layer 1013 is disposed on the buffer layer 1012, the channel region, the source electrode and the drain electrode of each transistor are disposed on the isolation layer 1013, and the first gate insulation layer 1014 is formed on the channel region, the source electrode and the drain electrode of the transistor, the first metal layer 302 is disposed on the first gate insulation layer 1014, the second gate insulation layer 1015 is disposed on the first metal layer 302, the second metal layer 303 is located on the second gate insulation layer 1015, the interlayer insulation layer ILD is located on the second metal layer 303, the conductive connection layer 304 is located on the interlayer insulation layer ILD, the passivation layer PVX is located on the first metal layer 302, the first planarization layer PLN1 is located on the passivation layer PVX, and a conductive layer 305 is located on the first planarization layer PLN1.

For example, as shown in FIG. 16, a second planarization layer PLN2 is located on the conductive layer 305, the first electrode 201 of the light-emitting element 20 is located on the second planarization layer PLN2, the pixel definition layer PDL and the spacer PS are located on the second planarization layer PLN2, the pixel definition layer PDL has an opening OPN, the opening OPN is configured to define the light-emitting area of the pixel unit, and the light-emitting area is the area of the light-exiting region, that is, the effective light-emitting area. The spacer PS is configured to support a fine metal mask during forming the light-emitting function layer 203.

For example, the opening OPN is the light-exiting area of the pixel unit. The light-emitting function layer 203 is located on the first electrode 201 of the light-emitting element 20, and the second electrode 202 of the light-emitting element 20 is located on the light-emitting function layer 203, and an encapsulation layer CPS is provided on the light-emitting element 20. The encapsulation layer CPS includes a first encapsulation layer CPS1, a second encapsulation layer CPS2 and a third encapsulation layer CPS3. For example, the first encapsulation layer CPS1 and the third encapsulation layer CPS3 are inorganic material layers, and the second encapsulation layer CPS2 is an organic material layer. Sandwiching an organic material layer between two inorganic material layers can better block the influence of water and oxygen on the light-emitting element 20, for example, the first electrode 201 is the anode of the light-emitting element 20, and the second electrode 202 is the cathode of the light-emitting element 20, but the embodiments of the present disclosure are not limited to this. Those skilled in the art can also adjust the arrangement position and the shape of the first electrode 201 of the light-emitting element as needed.

For example, as shown in FIG. 16, the first electrode 201 of the light-emitting element 20 is electrically connected to the connection electrode CEf through the via hole H9 penetrating the second planarization layer PLN2.

For example, the light-emitting element 20 includes an organic light-emitting diode. The light-emitting function layer 203 is located between the second electrode 202 and the first electrode 201. The second electrode 202 is located on the side of the first electrode 201 away from the base substrate 1011, and the light-emitting function layer 203 at least includes a light-emitting layer, and may also include at least one selected from a group consisting of a hole transport layer, a hole injection layer, an electron transport layer and an electron injection layer.

For example, as shown in FIG. 6 and FIG. 16, the second electrode plate Cb of the storage capacitor has an opening OPN1, and the arrangement of the opening OPN1 is beneficial to realize the electrical connection between the connection electrode CEb and the gate electrode T10 of the driving transistor T1.

For example, the transistors in the pixel circuit of the embodiment of the present disclosure are all thin film transistors. For example, the first metal layer 302, the second metal layer 303, the conductive connection layer 304 and the conductive layer 305 are all made of a metal material. For example, both the first metal layer 302 and the second metal layer 303 are made of a metal material such as nickel, aluminum, and so on, but the embodiments of the present disclosure are not limited to this. For example, both the conductive connection layer 304 and the conductive layer 305 are made of a material such as titanium, aluminum, and so on, but the embodiments of the present disclosure are not limited to this. For example, the conductive connection layer 304 and the conductive layer 305 respectively adopt a structure formed by stacking three sub-layers of Ti/Al/Ti, but the embodiments of the present disclosure are not limited to this. For example, the base substrate 1011 may be a glass substrate or a polyimide substrate, but the embodiments of the present disclosure are not limited to this and the kind of the base substrate 1011 may be selected as required. For example, the first gate insulation layer 1014, the second gate insulation layer 1015, the interlayer insulation layer ILD, the passivation layer PVX, the first planarization layer PLN1, the second planarization layer PLN2, the pixel definition layer PDL, and the spacer PS are all made of an insulation material. The materials of the first electrode 201 and the second electrode 202 of the light-emitting element may be selected as required. In some embodiments of the present disclosure, the first electrode 201 may be formed by using at least one of transparent conductive metal oxide and silver, but the embodiments of the present disclosure are not limited to this. For example, the transparent conductive metal oxide includes indium tin oxide (ITO), but the embodiments of the present disclosure are not limited to this. For example, the first electrode 201 may also adopt a structure in which three sublayers of ITO-Ag-ITO are arranged. In some embodiments of the present disclosure, the second electrode 202 may be made of a metal with a low work function, and at least one of magnesium and silver may be used, but the embodiments of the present disclosure are not limited to this.

For example, in the embodiments of the present disclosure, the preparation process of the display substrate is as follows: the pixel circuits are formed on the base substrate 1011 to form part of the structure of the display substrate shown in FIG. 15, and the light-emitting elements are formed on the basis of the display substrate shown in FIG. 15, that is, the pixel circuits are closer to the base substrate than the light-emitting elements.

At least one embodiment of the present disclosure further provides a display device including any one of the display substrates mentioned above. For example, the display device includes an OLED, or, a display product driven by a high frame rate and including an OLED. For example, the display device includes TV, digital camera, mobile phone, watch, tablet computer, notebook computer, navigator and other products or components with display function.

For example, the pixel circuit of 7T1C is described above as an example, and the embodiments of the present disclosure include but are not limited to this. It should be noted that the embodiments of the present disclosure do not limit the number of the thin film transistors and the number of capacitors included in the pixel circuit. For example, in other embodiments, the pixel circuit of the display substrate may also be a structure including other numbers of transistors, such as a 7T2C structure, a 6T1C structure, a 6T2C structure or a 9T2C structure, which is not limited by the embodiments of the present disclosure.

In the embodiment of the present disclosure, the elements located in the same layer may be formed through the same patterning process from the same film. For example, the elements located in the same layer may be located on the surface of the same element away from the base substrate.

In the embodiments of the present disclosure, the patterning or patterning process may only include a photolithography process, or include a photolithography process and an etching process, or may include other processes for forming predetermined patterns such as printing process and inkjet process. The photolithography process refers to the process including film formation, exposure, development, etc., using photoresist, mask, exposure machine, etc. to form patterns. The corresponding patterning process can be selected according to the structure formed in the embodiment of the present disclosure.

For example, in the embodiments of the present disclosure, the element A partially overlaps with the element B, which means that a part of the element A overlaps with the element B, or a part of the element B overlaps with the element A, or a part of the element A overlaps with a part of the element B. The element A and the element B are two different elements.

The following statements should be noted:

(1) The accompanying drawings only involve the structure(s) in connection with the embodiment(s) of the present disclosure, and other structure(s) can be referred to common design(s).

(2) In the case of no conflict, the features in the same embodiment and different embodiments of the present disclosure can be combined with each other.

The above are only specific embodiments of the present disclosure, but the protection scope of the present disclosure is not limited thereto. Any person skilled in the art can easily think of changes or substitutions within the technical scope disclosed in the present disclosure. It should be covered within the protection scope of the present disclosure. Therefore, the protection scope of the present disclosure should be subject to the protection scope of the claims.

1. A display substrate comprising:
a base substrate;
a plurality of pixel units, on the base substrate, wherein each of the pixel units comprises a pixel circuit, the pixel circuit comprises a first reset transistor and a threshold compensation transistor;
the display substrate further comprises a semiconductor layer, a first metal layer, a second metal layer and a conductive layer which are stacked on the base substrate, wherein
the first metal layer comprises a first reset control signal line and a gate signal line that extend in a first direction and are arranged in a second direction, and the first direction intersects the second direction;
the semiconductor layer comprises a first connection part extending in the second direction, and an orthographic projection of the first connection part on the base substrate is between an orthographic projection of the first reset control signal line on the base substrate and an orthographic projection of the gate signal line on the base substrate, and one end of the first connection part is electrically connected to a first electrode of the first reset transistor;
the conductive layer comprises data lines extending in the second direction, and each of the pixel units is between two of the data lines adjacent to each other;
the second metal layer comprises a plurality of shielding blocks, the plurality of shielding blocks are in one-to-one correspondence with the plurality of pixel units, and an orthographic projection of each of the shielding blocks on the base substrate at least partially overlaps with an orthographic projection of a corresponding one of the first connection part on the base substrate, and orthographic projections of the shielding blocks corresponding to two adjacent columns of sub-pixels on the base substrate are symmetrical with respect to a straight line that is between two of the shielding blocks adjacent to each other in the first direction and extends in the second direction.

2. The display substrate according to claim 1, wherein the threshold compensation transistor is a double-gate type thin film transistor, and the orthographic projection of each of the shielding blocks on the base substrate at least partially overlaps with an orthographic projection of a conductive active layer between two gate electrodes of the threshold compensation transistor comprised in a corresponding one of the pixel circuit on the base substrate.

3. The display substrate according to claim 2, wherein each of the shielding blocks comprises a first shielding part extending in a straight line along the second direction, and a second shielding part and a third shielding part that extend in a zigzag line, and the second shielding part and the third shielding part are connected at an end position of the first shielding part close to the second shielding part, and the second shielding part and the third shielding part form an accommodation space so that an orthographic projection of a part of the first connection part on the base substrate is in an orthographic projection of the accommodation space on the base substrate, and an orthographic projection of another part of the first connection part on the base substrate overlaps with an orthographic projection of the first shielding part on the base substrate.

4. The display substrate according to claim 3, wherein a first sub-shielding part of the second shielding part directly connected to the first shielding part extends in a direction opposite to the first direction, and a second sub-shielding part of the third shielding part directly connected to the first shielding part extends in the first direction, and a length of the first sub-shielding part in the first direction is smaller than that of the second sub-shielding part in the first direction.

5. The display substrate according to claim 3, wherein an overlapping region formed by overlapping the orthographic projection of the first shielding part on the base substrate and the orthographic projection of the first connection part on the base substrate has a first overlapping area, an overlapping region formed by overlapping an orthographic projection of the third shielding part on the base substrate and the orthographic projection of the conductive active layer between the two gate electrodes of the threshold compensation transistor on the base substrate has a second overlapping area, and the first overlapping area is larger than the second overlapping area.

6. The display substrate according to claim 3, wherein the data lines are configured to provide data signals to the pixel circuits corresponding to the data lines, and the plurality of the pixel units comprise two adjacent pixel units in a same column, and two of the data lines adjacent to each other are respectively connected to the two adjacent pixel units, and orthographic projections of the two of the data lines adjacent to each other on the base substrate overlap with an orthographic projection of each of the two adjacent pixel units in the same column on the base substrate respectively.

7. The display substrate according to claim 6, wherein two rows of pixel units arranged in sequence in the second direction and two columns of pixel units arranged in sequence in the first direction constitute a repeating unit, and the pixel unit in a first row and a first column and the pixel unit in the first row and a second column are symmetrical with respect to a straight line extending in the second direction; the pixel unit in the first column and a second row and the pixel unit in the second row and the second column of are symmetrical with respect to a straight line extending in the second direction.

8. The display substrate according to claim 7, further comprising a conductive connection layer arranged between the second metal layer and the conductive layer, wherein the conductive connection layer comprises an initialization signal connection line extending in the second direction, a first initialization signal line and a second initialization signal line are arranged in the second metal layer, the first initialization signal line is closer to the first reset control signal line than the second initialization signal line, and one end of the initialization signal connection line is electrically connected to the second initialization signal line.

9. The display substrate according to claim 8, wherein the first reset transistor comprises a second electrode, and the second electrode of the first reset transistor comprised in the pixel unit in the first row and the first column and the second electrode of the first reset transistor comprised in the pixel unit in the first row and the second column are both connected to other end of the initialization signal connection line between them.

10. The display substrate according to claim 9, wherein one of the repeating units corresponds to one of the initialization signal connection line.

11. The display substrate according to claim 8, wherein the conductive layer further comprises a first power line extending in the second direction, the first power line is between the data lines adjacent to each other, and an orthographic projection of the first power line on the base substrate at least partially overlaps with the orthographic projection of each of the shielding blocks on the base substrate.

12. The display substrate according to claim 11, wherein the first power line is bent and extended in the second direction, and a same one of the first power line corresponds to a plurality of the pixel units in a same column.

13. The display substrate according to claim 12, wherein a planar shape of the first power line is a stepped shape.

14. The display substrate according to any one of claims 11 to 13, wherein the conductive connection layer further comprises a power connection line extending in the second direction, and the first power line comprises a first part, a second part and a third part that protrude to a side of the data line corresponding to the first power line, the first part, the second part and the third part are sequentially arranged in the second direction, and an orthographic projection of the first part on the base substrate overlaps with an orthographic projection of the power connection line on the base substrate.

15. The display substrate according to claim 14, wherein the conductive connection layer further comprises a first connection electrode extending in the second direction, and an orthographic projection of the second part comprised in the first power line on the base substrate overlaps with an orthographic projection of the first connection electrode on the base substrate.

16. The display substrate according to claim 14, wherein the pixel circuit further comprises a driving transistor, a first power terminal and a storage capacitor, a first electrode plate of the storage capacitor is connected to a gate electrode of the driving transistor, and a second electrode plate of the storage capacitor is connected to the first power terminal, and an orthographic projection of the third part comprised in the first power line overlaps with an orthographic projection of the second electrode plate on the base substrate.

17. The display substrate according to claim 14, wherein the orthographic projection of the power connection line on the base substrate, the orthographic projection of the first shielding part on the base substrate, and an orthographic projection of a channel region of the first reset transistor on the base substrate overlap.

18. The display substrate according to claim 17, further comprising a second reset control signal line and a light-emitting element, wherein the pixel circuit further comprises a second reset transistor, a gate electrode of the second reset transistor is connected to the second reset control signal line, a first electrode of the second reset transistor is connected to the second initialization signal line, and a second electrode of the second reset transistor is connected to a first electrode of the light-emitting element.

19. The display substrate according to claim 18, wherein the gate signal line is configured to provide a scan signal to the pixel circuit, and the pixel circuit further comprises a data writing transistor, a gate electrode of the data writing transistor is connected to the gate signal line, a first electrode of the data writing transistor is connected to the data line, and a second electrode of the data writing transistor is connected to a first electrode of the driving transistor.

20. The display substrate according to claim 19, wherein a first electrode of the threshold compensation transistor is connected to a second electrode of the driving transistor, and a second electrode of the threshold compensation transistor is connected to a gate electrode of the driving transistor; the gate electrode of the threshold compensation transistor is connected to the gate signal line; and
the gate electrode of the driving transistor is connected to the second electrode of the threshold compensation transistor.

21. The display substrate according to claim 16, wherein the pixel circuit further comprises a first light-emitting control transistor and a second light-emitting control transistor,
a gate electrode of the first light-emitting control transistor is connected to a light-emitting control signal line, a first electrode of the first light-emitting control transistor is connected to the first power terminal, and a second electrode of the first light-emitting control transistor is connected to a first electrode of the driving transistor;
a gate electrode of the second light-emitting control transistor is connected to the light-emitting control signal line, a first electrode of the second light-emitting control transistor is connected to a second electrode of the driving transistor, and a second electrode of the second light-emitting control transistor is connected to a first electrode of the light-emitting element.

22. A display device, comprising the display substrate according to any one of claims 1 to 21.
